(19) United States
(12) Patent Application Publication
(10) Pub. No.: US 2023/0012003 A1
(43) Pub. Date: Jan. 12, 2023

(54) META-LENS SYSTEMS AND TECHNIQUES

(71) Applicant: QUALCOMM Incorporated, San Diego, CA (US)

(72) Inventors: Jian MA, San Diego, CA (US); Biay-Cheng HSEIH, Irvine, CA (US); Matthieu Jean Olivier DUPRE, La Jolla, CA (US); Sergiu Radu GOMA, Sedona, AZ (US)

(21) Appl. No.: 17/857,790

(22) Filed: Jul. 5, 2022

Related U.S. Application Data
(60) Provisional application No. 63/219,321, filed on Jul. 7, 2021.

(51) Int. Cl. G02B 1/00; G02B 7/02

(52) U.S. Cl. CPC G02B 1/002; G02B 7/021

(57) ABSTRACT

Systems and techniques are provided for meta-lens cameras. For example, an apparatus can include a first substrate including a first aperture and a second substrate including a first meta-lens. The first substrate and the second substrate are mechanically coupled such that at least a first portion of the first aperture is disposed over at least a second portion of the first meta-lens.

### CROSS-REFERENCE TO RELATED APPLICATIONS

This application claims the benefit of U.S. Provisional Application No. 63/219,321, filed Jul. 7, 2021, the disclosures of which is hereby incorporated by reference, in its entirety and for all purposes.

### FIELD

The present disclosure generally relates to optical systems utilizing meta-lenses. In some examples, aspects of the present disclosure are related to systems and techniques related to meta-lens assemblies.

### BACKGROUND

Many devices and systems include optical elements, such as lenses for focusing light onto an image sensor. For example, a camera or a device including a camera with such optical elements can capture a frame or a sequence of frames of a scene (e.g., a video of a scene). In order to achieve desirable optical characteristics (e.g., including but not limited to sharpness, wide field of view, among others), the camera or camera device can utilize refractive lenses to focus incoming light onto an optical sensor. In some cases, a lens for a camera device can be a compound lens that includes multiple refractive lens elements stacked together. In some cases, the overall thickness of the compound lens stack can add additional size to a device that includes the compound lens stack.

Meta-lenses can provide an alternative to refractive lenses. Meta-lenses can be formed by fabricating nanometer scale (also referred to herein as nanoscale) geometric structures on a substrate material. The nanoscale geometric structures can control the transmission, polarization, and phase of light passing through the nanoscale geometric structures based on physical characteristics (e.g., height, width, length, diameter, etc.) of the nanoscale geometric structures. In some cases, meta-lenses can be fabricated using a fabrication technique, such as electron beam (e-beam) lithography.

### SUMMARY

In some examples, systems and techniques are described for meta-lens cameras. According to at least one illustrative example, an apparatus is provided. The apparatus includes a first substrate including a first aperture and a second substrate including a first meta-lens. The first substrate and the second substrate are mechanically coupled such that at least a first portion of the first aperture is disposed over at least a second portion of the first meta-lens.

In another example, a method of assembling an optical system is provided. The method of assembling the optical system includes mechanically coupling a first substrate comprising a first aperture and a second substrate comprising a first meta-lens. Upon mechanically coupling the first substrate and the second substrate: at least a first portion of the first aperture is disposed over at least a second portion of the first meta-lens.

In another example, an apparatus is provided. The apparatus includes means for providing a first aperture and means for providing a first meta-lens. The means for providing the first aperture and the means for providing the first meta-lens are mechanically coupled such that at least a first portion of the first aperture is disposed over at least a second portion of the first meta-lens.

In some aspects, the first substrate comprises a second aperture; the second substrate comprises a second meta-lens; and the first substrate and the second substrate are mechanically coupled such that a third portion of the second aperture is disposed over a fourth portion of the second meta-lens.

In some aspects, a first meta-lens module comprises the first aperture and the first meta-lens.

In some aspects, a second meta-lens module comprises the second aperture and the second meta-lens.

In some aspects, the first substrate comprises a first wafer and a plurality of apertures; the plurality of apertures comprises the first aperture; the second substrate comprises a second wafer and a plurality of meta-lenses; and the plurality of meta-lenses comprises the first meta-lens.

In some aspects, the method and apparatuses described above further comprise: a third substrate comprising an optical sensor, wherein the first substrate, the second substrate, and the third substrate are mechanically coupled such that: at least the first portion of the first aperture is disposed above at least the second portion of the first meta-lens; at least a third portion of the first meta-lens is spaced apart from at least a fourth portion of the optical sensor; and at least the second portion of the first meta-lens is disposed over at least a fifth portion of the optical sensor.

In some aspects, the third substrate comprises a third wafer and a plurality of optical sensors, wherein the plurality of optical sensors comprises the optical sensor.

In some aspects, the plurality of apertures is disposed on the first substrate with a first pitch; the plurality of meta-lenses is disposed on the second substrate with a first second pitch; the plurality of optical sensors is disposed on the third substrate with a second pitch; and the first pitch and the second pitch are equal.

In some aspects, the plurality of optical sensors is disposed on the third substrate with a third pitch; and the first pitch, the second pitch, and the third pitch are equal.

In some aspects, a fourth wafer comprises a spacer structure disposed between the first wafer and the second wafer and wherein the first wafer, the second wafer, and the fourth wafer are mechanically coupled.

In some aspects, the first meta-lens and the optical sensor are separated by a focal length of the first meta-lens.

In some aspects, the method and apparatuses described above further comprise an optical filter disposed between the first substrate and the second substrate.

In some aspects, the method and apparatuses described above further comprise a spacer structure disposed between first substrate and the second substrate.

In some aspects, the optical filter is disposed between the first substrate and the spacer structure.

In some aspects, the optical filter is disposed between the second substrate and the spacer structure.

In some aspects, the optical filter comprises a band pass filter.

In some aspects, the first substrate comprises a first silicon substrate and the second substrate comprises a second silicon substrate.

In some aspects, the first substrate comprises a first glass substrate and the second substrate comprises a second glass substrate.

In some aspects, the spacer structure comprises a third silicon substrate.

In some aspects, the spacer structure comprises a structure disposed on the first substrate.

In some aspects, the structure disposed on the first substrate comprises a plurality of pillars positioned outside of a periphery of the first meta-lens.

In some aspects, the structure disposed on the first substrate comprises a continuous structure surrounding a periphery of the first meta-lens.

In some aspects, the structure disposed on the first substrate comprises a dam structure.

In some aspects, the structure disposed on the first substrate comprises a polyimide material.

In some aspects, the structure disposed on the first substrate comprises an opening and wherein the first meta-lens is positioned within the opening.

In some aspects, a fifth substrate is mechanically coupled to the first substrate and the second substrate, wherein the fifth substrate comprises a reconfigurable instruction cell array (RICA).

In some aspects, the RICA is configured to receive image data from an optical sensor.

In some aspects, the RICA is further configured to perform one or more image processing operations on the image data.

In some aspects, the one or more image processing operations comprise generating a depth map, generating a composite image, or stitching together at least a portion of a first image and at least a portion of a second image.

In some aspects, the method and apparatuses described above further comprise: a sixth substrate, different from the second substrate, comprising a third meta-lens disposed thereon, wherein at least an eighth portion of the first meta-lens is disposed above at least a ninth portion of the third meta-lens.

In some aspects, the first meta-lens and the third meta-lens comprise a compound lens.

In another example, a method of optical detection is provided. The method of optical detection includes receiving light at an aperture, wherein a first substrate comprises the aperture and the aperture allows at least a first portion of the light to pass through the first substrate and prevents at least a second portion of the light from passing through the first substrate; receiving at least the first portion of the light at a meta-lens, wherein a second substrate comprises the meta-lens and the meta-lens focuses at least the first portion of the light at a focal plane; and detecting, by an optical sensor, at least the first portion of the light focused by the meta-lens, wherein a third substrate comprises the optical sensor.

In some aspects, the first substrate, the second substrate, and the third substrate are mechanically coupled.

In some aspects, the meta-lens and the optical sensor are separated by a separation equal to a focal length of the meta-lens.

In some aspects, a spacer structure provides at least a portion of the separation.

In some aspects, the methods and apparatuses described above further comprise generating at least a portion of an image based on detecting the first portion of the light.

In some aspects, the methods and apparatuses described above further comprise receiving at least the portion of the image at a RICA.

In some aspects, a fourth substrate comprises the RICA and the first substrate, the second substrate, the third substrate, and the fourth substrate are mechanically coupled.

In some aspects, the RICA is configured to perform one or more image processing operations on at least the portion of the image.

In some aspects, the methods and apparatuses described above further comprise generating a depth map based on at least the portion of the image, generating a composite image based on at least the portion of the image, or stitching together at least the portion of the image and at least a portion of another image.

In some aspects, one or more of the apparatuses described above is, is part of, or includes a camera or multiple cameras, a mobile device (e.g., a mobile telephone or so-called “smart phone” or other mobile device), a wearable device (e.g., a smartwatch, a fitness tracking device, etc.), an extended reality device (e.g., a virtual reality (VR) device, an augmented reality (AR) device, or a mixed reality (MR) device), a personal computer, a laptop computer, a server computer, a vehicle (e.g., a computing device of a vehicle), or other device. In some aspects, the apparatus further includes one or more displays for displaying one or more images, notifications, and/or other displayable data. In some aspects, the apparatus can include one or more sensors, which can be used for determining a location and/or pose of the apparatus, a state of the apparatus, and/or for other purposes.

This summary is not intended to identify key or essential features of the claimed subject matter, nor is it intended to be used in isolation to determine the scope of the claimed subject matter. The subject matter should be understood by reference to appropriate portions of the entire specification of this patent, any or all drawings, and each claim.

The foregoing, together with other features and embodiments, will become more apparent upon referring to the following specification, claims, and accompanying drawings.

### BRIEF DESCRIPTION OF THE DRAWINGS

Illustrative embodiments of the present application are described in detail below with reference to the following figures:

FIG. 1A is a perspective view of an example meta-lens, in accordance with some examples;

FIG. 1B is a lateral view of an example meta-lens, in accordance with some examples;

FIG. 1C is a perspective view of an example meta-lens unit cell, in accordance with some examples;

FIG. 1D is a top-down view of an example meta-lens unit cell, in accordance with some examples;

FIG. 1E illustrates a plot of pillar diameter against phase, in accordance with some examples;

FIG. 2A illustrates a plot of pillar position against phase, in accordance with some examples;

FIG. 2B illustrates a plot of pillar position against diameter, in accordance with some examples;

FIG. 2C illustrates an example ray diagram for a hyperbolic meta-lens, in accordance with some examples;

FIG. 2D illustrates an example ray diagram for an optimized meta-lens, in accordance with some examples;

FIG. 2E illustrates an example spot diagram at the focal plane for a hyperbolic meta-lens, in accordance with some examples;

FIG. 2F illustrates an example spot diagram at the focal plane for an optimized meta-lens, in accordance with some examples;

FIG. 3 is a diagram illustrating example magnified portions of a meta-lens, in accordance with some examples;

FIG. 4 are diagrams illustrating lateral views of a compound lens and a corresponding meta-lens, in accordance with some examples;

FIG. 5A through FIG. 5F are diagrams illustrating a meta-lens wafer stackup fabrication technique, in accordance with some examples;

FIG. 6A through FIG. 6E are diagrams illustrating cross-sections of example meta-lens stackup configurations, in accordance with some examples;

FIG. 7A through FIG. 7D are diagrams illustrating an example nanoimprinting technique for fabricating meta-lenses, in accordance with some examples;

FIG. 8 is a diagram illustrating an example meta-lens wafer stackup, in accordance with some examples;

FIG. 9A through FIG. 9C are diagrams illustrating an example meta-lens wafer stackup, in accordance with some examples;

FIG. 10 is a diagram illustrating another example meta-lens wafer stackup, in accordance with some examples;

FIG. 11 is a flow diagram illustrating an example of a process for assembling a meta-lens wafer stackup, in accordance with some examples;

FIG. 12 is a diagram illustrating an example of a computing system for implementing certain aspects described herein.

### DETAILED DESCRIPTION

Certain aspects and embodiments of this disclosure are provided below. Some of these aspects and embodiments may be applied independently and some of them may be applied in combination as would be apparent to those of skill in the art. In the following description, for the purposes of explanation, specific details are set forth in order to provide a thorough understanding of embodiments of the application. However, it will be apparent that various embodiments may be practiced without these specific details. The figures and description are not intended to be restrictive.

The ensuing description provides exemplary embodiments only, and is not intended to limit the scope, applicability, or configuration of the disclosure. Rather, the ensuing description of the exemplary embodiments will provide those skilled in the art with an enabling description for implementing an exemplary embodiment. It should be understood that various changes may be made in the function and arrangement of elements without departing from the spirit and scope of the application as set forth in the appended claims.

Many devices and systems include optical elements, which can include lenses for focusing light onto an image sensor. In one example, a camera or a device including a camera (e.g., a mobile device, an extended reality (XR) device, etc.) with optical elements can capture a frame or a sequence of frames of a scene (e.g., a video of a scene). In order to achieve desirable optical characteristics (e.g., sharpness, wide field of view, etc.), the camera or camera device can utilize refractive lenses to focus incoming light on an image sensor. In some cases, a lens for a camera device can include compound lens comprising multiple refractive lens elements stacked together. In some cases, the overall thickness of the compound lens stack can add additional size to a device that includes the camera lens stack as part of a camera system.

In contrast to a refractive lens, a meta-lens is a lens made with meta-surface technology. A meta-surface is a flat optical component designed at the nanometer (nm) scale with small geometrical features on the surface. In some cases, the small geometrical features can control the transmission, polarization, and phase of light passing through the meta-lens. In one illustrative example, the small geometric features making up a meta-lens can include pillars or columns (sometimes referred to as nanopillars). In some cases, the effect on light passing through the pillars can depend on the geometry of the pillars such as the height of the pillars, diameter of the pillars, and pitch of the pillars. In some implementations, the pillars can have a constant height and the effect on light passing through the pillars can be varied by providing pillars with different diameters.

In some cases, meta-lenses can be fabricated in a piece-by-piece fashion using an electron beam (e-beam) lithography technique. In the e-beam lithography technique for fabricating meta-lenses, a focused e-beam can be scanned across a surface of a substrate to create a pattern corresponding to the desired meta-surface structure. In some cases, the surface of the substrate can be coated in a resist material that changes characteristics when exposed to e-beam energy. Depending on the type of resist material used, either the exposed resist material or the non-exposed resist material can be selectively removed while the other portion remains on the surface of the substrate. Where the resist material is selectively removed, the substrate can be exposed and can be etched (e.g., by wet etching, dry etching, reactive-ion etching (RIE), or the like) to remove a portion of the substrate material. In some cases, the etching process can create geometric features of the meta-surface on the surface of the substrate material to form a meta-lens. In some cases, because the geometric features of the meta-surface have to be patterned onto the resist material by directing a focused e-beam at the resist material, the process of fabricating can be time consuming and costly.

Systems, apparatuses, processes (also referred to as methods), and computer-readable media (collectively referred to as “systems and techniques”) are described herein for manufacturing meta-lenses and optical systems including meta-lenses in a scalable manner. For example, semiconductor manufacturing technology is used to produce multiple devices (e.g., microprocessors, application specific integrated circuits, or the like) simultaneously on a single silicon wafer. In contrast to the e-beam lithography technique described above, features fabricated on the surface of the silicon wafer are not individually drawn. Instead, the features (or a negative representation of the features) of a device can be patterned on to a mask. The features of a single device can be repeated in array to fill the area (or a portion of the area) of a surface of a silicon wafer with multiple devices. With a single exposure of light, the pattern on the mask can be transferred to a photosensitive resist (photoresist) material. In the case of semiconductor manufacturing, multiple masks may be used to fabricate different features of a device such as metal layers, transistors, passivation layers, mechanical structures or the like. Accordingly, it would be advantageous if the photolithography process used for manufacturing semiconductors could also be used to manufacture meta-lenses.

In some aspects, the silicon material used in many semiconductor manufacturing applications is transparent to certain wavelengths of light. In some cases, optical applications can detect light at the wavelengths of light where silicon is transparent. Accordingly, silicon can be a suitable substrate material for fabricating meta-lenses for image sensing applications where silicon is transparent to the wavelengths of light being detected. For example, applications using short-wave infrared (SWIR). In some cases, SWIR sensitive image sensors can be fabricated using semiconductor fabrication techniques. For example, SWIR sensitive imagers can be fabricated on silicon wafers using Germanium-Silicon (GeSi) based complementary metal-oxide-semiconductor (CMOS) technology. In some cases, the semiconductor manufacturing technology described above can be used to fabricate meta-lenses on silicon wafers.

For some optical applications silicon may not be a suitable substrate for fabricating meta-lenses because the wavelengths of light relevant to the optical application may not be able to pass through the silicon. For example, silicon is opaque at visible light wavelengths. Many optical applications detect light at visible wavelengths. In such cases, a material that is transparent at visible light wavelengths can be a suitable substrate for fabricating meta-lenses. In one illustrative example, meta-lenses can be fabricated on a glass substrate. The semiconductor fabrication techniques described above are not currently available for use with a glass substrate. In some cases, fabrication techniques used with glass substrates may not be able to fabricate the nanoscale geometric features that make up meta-lenses. In some cases, nanoimprinting lithography technology can be used to fabricate meta-lenses on a glass substrate. In some cases, nanoimprinting lithography technology can utilize a stamp with a pattern that includes a meta-lens or any array of meta-lenses to make an imprint in a polymer layer. In some cases, the portions of the polymer layer that remain after imprinting can act as a resist material during an etching process. In some cases, after the etching process, the geometric features making up the meta-lens or array of meta-lenses can be formed in a device layer disposed on top of the glass substrate. In one illustrative example, the device layer can include a Titanium Dioxide (TiO₂) material.

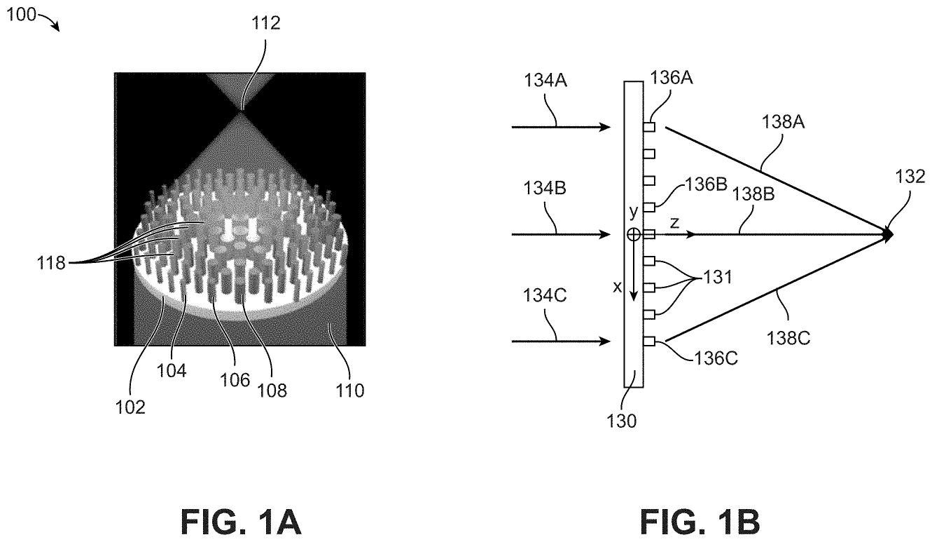

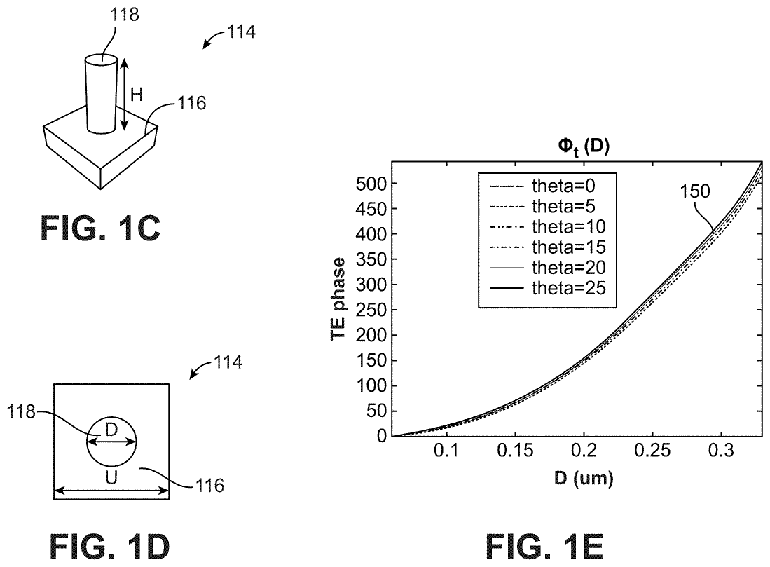

Various aspects of the techniques described herein will be discussed below with respect to the figures. FIG. 1A through FIG. 1C illustrate views of an example meta-lens. In the illustrated example of FIG. 1A, a meta-lens 100 includes a substrate 102 (also referred to as a base) having multiple pillars 118 including pillars 104, 106, 108 disposed on the surface of the substrate 102. In some cases, the pillars 118 can be an example of nanoscale geometric structures forming a meta-surface. The pillars 104, 106, 108 can be nanostructures having a height on the nanometer scale. In some implementations, the height of the nanostructures (e.g., pillars 118) can be on the order of the wavelength of light relevant to a particular application. In one illustrative example, a pillar height between 1100 nanometer (nm) and 1200 nm can be used for a meta-lens in a SWIR application (e.g., for wavelengths between 1380 nm and 1550 nm). In another illustrative example, a pillar height between 300 nm and 400 nm can be used for a meta-lens in a visible light application (e.g., for wavelengths between 350 nm and 800 nm) In some implementations, the pillars 104, 106, and 108 can have a common height H. In the illustrated example of FIG. 1A, the pillars 104, 106, 108 can have different diameters, where the pillar 104 is shown with the smallest diameter, the pillar 106 is shown with a diameter larger than the pillar 104, and the pillar 108 is shown with a diameter larger than pillar 104 and pillar 106. In the illustration of FIG. 1A, additional pillars of different sizes disposed on the substrate 102 are also shown. FIG. 1A illustrates a column of light 110 incident upon the meta-lens 100. As will be explained in more detail below, the pillars of the meta-lens 100, including pillars 104, 106, 108 can shift the phase of the rays of the column of light 110 so that the rays of the incident column of light 110 converge to a focal point 112 with a common phase. In some cases, the column of light is collimated. In some cases, the distance between the meta-lens 100 and the focal point 112 can be referred to as the focal distance of the meta-lens 100. While the examples of this disclosure include example meta-lenses utilizing pillars 118 as the geometric features forming a meta-surface that forms the meta-lens, the systems and techniques described herein can be used with meta-lenses that include features other than pillars without departing from the scope of the present disclosure.

FIG. 1B illustrates a lateral view of an example meta-lens 130 that can be configured to focus light at a focal point 132. In some cases, the meta-lens 130 can include a plurality of pillars 131 (which can correspond to pillars 118 shown in FIG. 1A) on one surface of the meta-lens 130. The pillars 118 illustrated in FIG. 1B are shown for illustration are not shown to scale. In addition, the number, height, diameter, and/or pitch of the pillars 118 shown in FIG. 1B are only provided as an example. Other meta-lens configurations can be used without departing from the scope of the present disclosure. For example, each individual pillar of the pillars 118 shown in FIG. 1B could represent a group of pillars in a meta-lens. In the illustrated example of FIG. 1B, the pillars 136A, 136B, 136C can provide different phase delays to incoming light. For example, light passing through pillar 136B will experience a larger phase delay than pillar 136A or pillar 136C. In some cases, the pillars 136A, 136B, 136C can represent groups of pillars that provide different phases delays to incoming light. In the illustrated example of FIG. 1B, light rays 134A, 134B, 134C can be incident upon the meta-lens 130. In the illustrated example of FIG. 1B, light ray 134A passes through a first pillar 136A, light ray 134B passes through a second pillar 136B, and light ray 134C passes through a third pillar 136C. The light rays 138A, 138B, 138C represent the path of light rays 134A, 134B, 134C after passing through the respective pillars 136A, 136B, 136C. As illustrated in FIG. 1B, the rays 138A and 138C travel from edges of the meta-lens 130 and can travel a greater distance than the ray 138B to reach the focal point 132. In some implementations, each of the pillars 136A, 136B, 136C can be configured with a phase shift such that each of the rays 138A, 138B, 138C arrive at the focal point 132 with an identical phase. As will be explained with more detail below with respect to FIG. 1C through FIG. 1E, the phase shift experienced by light rays (e.g., 134A, 134B, 134C) passing through the pillars 136A, 136B, 136C can be controlled as a function of the geometry of the pillars 136A, 136B, 136C. In some cases, an amount of phase shift experienced by light passing through the pillar 118 can depend on the height H, the diameter D, the wavelength of the light, the angle of incidence, and the polarization of the light passing through the pillar.

FIG. 1C illustrates a perspective view and FIG. 1D illustrates a top-down view of a unit cell that can be used for designing a meta-lens (such as meta-lens 100) with desired optical characteristics. In the illustration of FIG. 1C and FIG. 1D, the unit cell 114 can include a base 116, which can be a portion of the substrate 102 of the meta-lens 100 shown in FIG. 1A. In some cases, the base 116 includes a pillar 118 disposed upon the base 116 and centered at the center of the unit cell 114. In some aspects, the unit cell can be a square with a width of U. In some implementations, the width U of the unit cell can be determined based on the wavelength (A) of light that the meta-lens is designed for. In some cases, the width U can be less than λ/2*NA where NA is the numerical aperture of the meta-lens. In some cases, the width U of a unit cell can be between 300 nm and 600 nm. The pillar 118 can have a height of H and a diameter of D. In some cases, the optical characteristics of each unit cell 114 can be configured based on the value selected for the value D of each unit cell. In some cases, a meta-lens can be constructed by arranging an array (also referred to as a lattice) of unit cells having pillars 118 of different diameters to achieve desired optical characteristics. In the case where each of the unit cells has an identical value of U, the pillars 118 can have a uniform pitch. Although a square unit cell and associated lattice are described herein with respect to FIGS. 1C and 1D, other unit cell shapes and lattice structures can be utilized without departing from the scope of the present disclosure. In one illustrative example, a hexagonal unit cell can be used to form a hexagonal or triangle lattice.

FIG. 1E illustrates multiple plots 150 of phase shift for light traveling through pillars of different diameters D. The illustrative example of FIG. 1E depicts the relationship between diameter and phase for transverse electric (TE) polarized light passing through the pillar 118. In the illustrated example of FIG. 1E, the horizontal axis represents diameter D in microns (μm) of a pillar 118 in a unit cell 114 and the vertical axis represents the amount of phase shift experienced by light that has passed through the pillar 118. The multiple plots 150 illustrate the amount of phase shift experienced by light for different angles of incidence theta. As shown in FIG. 1E, for a fixed pillar height H, the phase shift for light passing through the pillar 118 can increase as the diameter D of the pillar 118 increases.

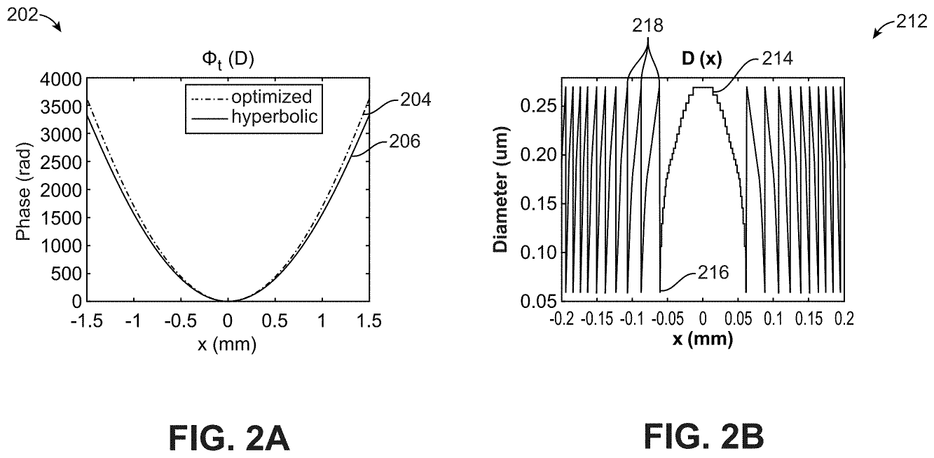

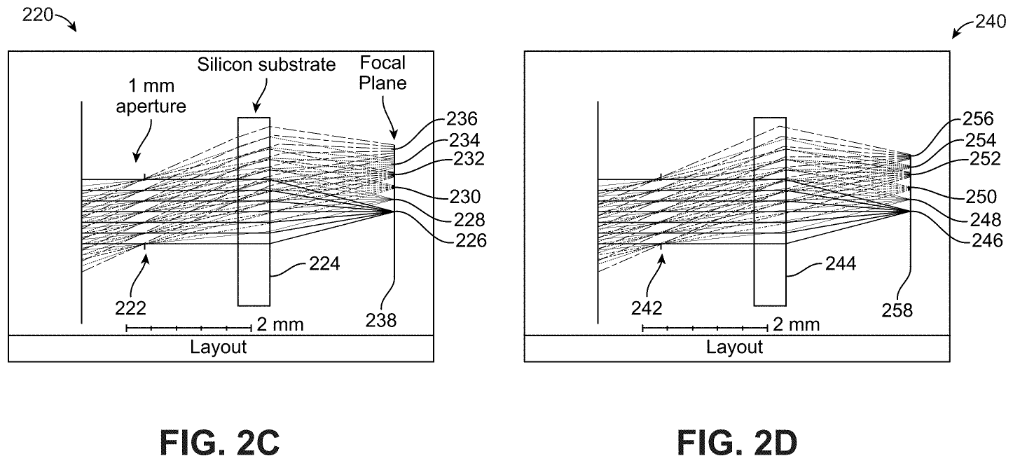

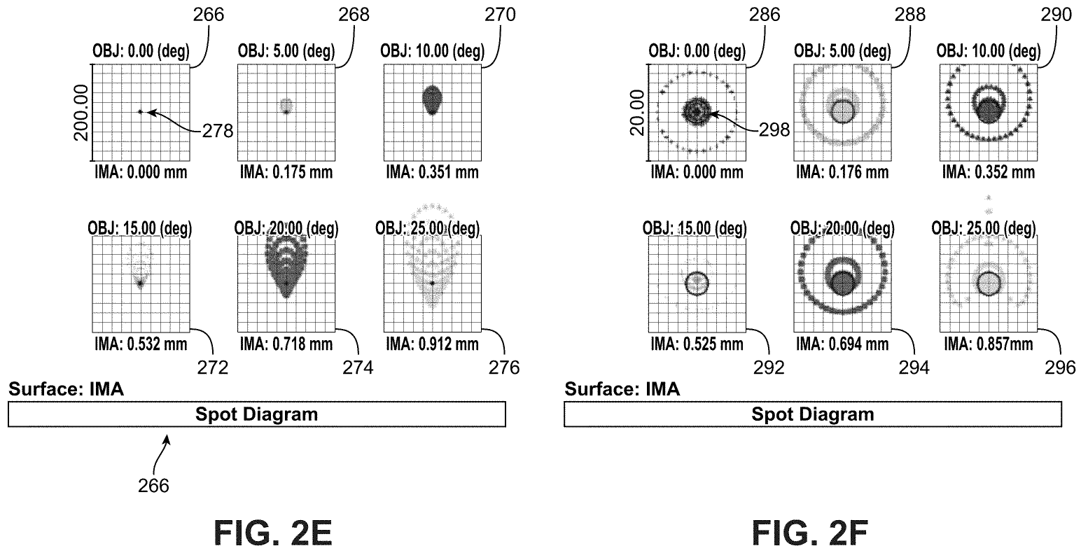

FIG. 2A illustrates a plot 202 of an example relationship between distance from the center of a meta-lens (e.g., meta-lens 100 shown in FIG. 1A) and an amount of phase shift for two example positive meta-lenses. In the illustrated examples of FIG. 2A and FIG. 2B, the meta-lens can be formed with an array unit cells (e.g., unit cell 114 shown in FIG. 1C and FIG. 1D above) having fixed height and width U and pillars of uniform height. In one illustrative example, the relationship between diameter D of the pillars included in the unit cells corresponds to the plots 150 shown in FIG. 1E above. In the illustrated example of FIG. 2A, the horizontal axis represents a distance from the center of the meta-lens and the vertical axis represents a phase shift to be imparted by at each distance to achieve particular desired meta-lens optical characteristics. The example plot 206 represents an example of pillar sizes for a meta-lens that is designed with optical characteristics of a hyperbolic refractive lens. In one illustrative example, the hyperbolic refractive lens relationship between phase and distance from the center of the lens illustrated by example plot 206 can represent a hyperbolic lens that provides an exact focus for normally incident light. The example plot 204 illustrates an example of an optimized meta-lens having a desired set of optical characteristics. In some cases, optimized characteristics for a meta-lens can be determined using an optical ray-tracing software. For example, the example plot 204 can represent a lens optimized to minimize an optical path difference (OPD) over a range of angles of incidence between 0 and 25 degrees. In one illustrative example, the lens represented by example plot 204 can be the result of an optimization of Equation (1) below.

OPD(r)=r²+f²−f+Σ₌₁⁶aₘ(r)^{2m} (1)

Where r is the radius of the meta-lens, f, is the focal length of the meta-lens, and aₘ are coefficients that are adjusted to determine the optimized OPD. As will be illustrated with respect to FIG. 2C through FIG. 2F below, optimizing the OPD can improve focusing for ray angles that are not normally incident to the meta-lens.

As described with respect to FIG. 1A through FIG. 1E above, an example meta-lens can be configured such that any incident ray passing through pillars (e.g., pillars 118) of the meta-lens can arrive at a focal point with an identical phase. In the illustration of FIG. 2A, the horizontal axis of the plot 202 represents a distance in millimeter (mm) from the center of the meta-lens and the vertical axis of the plot 202 represents an amount of phase shift in radians required to achieve the desired optical characteristics for the example meta-lens.

FIG. 2B illustrates a plot 212 of meta-lens pillar diameter plotted against distance from the center of a meta-lens. In the illustrated example of FIG. 2B, the horizontal axis represents a distance from the center of the meta-lens and the vertical axis represents a diameter of a pillar to achieve particular meta-lens optical characteristics. The example pillar diameters shown in FIG. 2B correspond to the plot 202 of the optimized meta-lens described above with respect to FIG. 2A. Because the propagation of light can be described as a sinusoid, the phase of the light can repeat every period of the wavelength of the light (e.g., every 360 degrees or every 2×pi (π) radians). As a result, the same pillar diameter can be used when, for example, the desired phase shift is 180 degrees as well as when the desired phase shift is 540 degrees. Accordingly, the plot 212 illustrates a range of pillar diameters that can provide phase shifts that correspond to the example plot 204 of an optimized meta-lens. In the illustrated example, the diameter D can have a maximum value at the center 214 of the meta-lens. In some cases, as the distance from the center 214 of the meta-lens increases, the diameter D of the pillars in the unit cells can decrease until a minimum diameter 216 is reached. At the distance from the center 214 of the meta-lens corresponding to the minimum diameter 216, the desired phase shift for the pillars can be 2 π radians separated from than the desired phase shift for the pillars at the center 214 of the meta-lens. In some cases, at each point where the desired phase shift is a multiple of 2 π radians separated from the phase shift from the pillars at the center 214 of the meta-lens, the diameter D of the pillars can be reset to the largest size. In some cases, the locations where the pillar diameter D resets to the largest value can be referred to as phase reset points 218.

FIG. 2C illustrates an example ray diagram 220 for a hyperbolic meta-lens. In one illustrative example, the hyperbolic lens shown in the ray diagram 220 can correspond to the example hyperbolic lens phase characteristics shown in example plot 206 of FIG. 2A above. FIG. 2C illustrates an aperture 222, a meta-lens 224, and light rays 226, 228, 230, 232, 234, 236. In the illustrated example of FIG. 2C, light rays 226 have an angle of incidence of 0 degrees, light rays 228 have an angle of incidence of 5 degrees, light rays 230 have an angle of incidence of 10 degrees, light rays 232 have an angle of incidence of 15 degrees, light rays 234 have an angle of incidence of 20 degrees, and light rays 236 have an angle of incidence of 25 degrees. As shown in FIG. 2C, the light rays 226, 228, 230, 232, 234, 236 show an increasing amount of spread at the focal plane 238 as the angle of incidence increases.

FIG. 2D illustrates an example ray diagram 240 for an optimized meta-lens configuration. In the illustrated example, the lens configuration can be optimized for wide-angle performance. In one illustrative example, the optimized lens 244 shown in the ray diagram 240 can correspond to the example optimized lens phase characteristics shown in example plot 204 shown in FIG. 2A above. FIG. 2D illustrates an aperture 242, a meta-lens 244, and light rays 246, 248, 250, 252, 254, 256. In the illustrated example of FIG. 2D, light rays 246 can have an angle of incidence of 0 degrees, light rays 248 can have an angle of incidence of 5 degrees, light rays 250 can have an angle of incidence of 10 degrees, light rays 252 can have an angle of incidence of 15 degrees, light rays 254 can have an angle of incidence of 20 degrees, and light rays 256 can have an angle of incidence of 25 degrees. As shown in FIG. 2D, the light rays 246, 248, 250, 252, 254, 256 show a relatively reduced amount of spread at the focal plane 258 when compared to the light rays 226, 228, 230, 232, 234, 236 shown in FIG. 2C.

In one illustrative example, the example meta-lenses 224 and 244 shown in FIG. 2C and FIG. 2D, respectively, can represent meta-lenses configured as follows: the meta-lenses 224 and 244 can be designed for a wavelength of 1380 nm or 1550 nm; the apertures 222 and 242 can have a 1 mm diameter; a spacing between the apertures 222, 242 and the respective meta-lenses 224, 244 can be 1.5 mm; the meta-lenses 224, 244 can be fabricated on a 0.5 mm thick crystalline silicon wafer substrate; and the meta-lenses 224, 244 can have a focal length of 2 mm.

FIG. 2E illustrates spot diagrams at the focal plane 238 for the light rays 226, 228, 230, 232, 234, 236 passing through meta-lens 224 as shown in FIG. 2C. In the spot diagrams 266, 268, 270, 272, 274, 276 the plotted grids represent an area with dimensions 200 μm×200 μm and the center of each grid can correspond to ideal focal point at the focal plane (e.g., focal plane 238 shown in FIG. 2C). In the illustration of FIG. 2E, each of the spot diagrams 266, 268, 270, 272, 274, 276 includes a circle representing the diffraction limit for focusing the incident light at the focal plane. For example, circle 278 (which may appear as a dot) shows the diffraction limit illustrated on the spot diagram 266. Each of the remaining spot diagrams 268, 270, 272, 274, 276 include a similar circle (not labeled). As shown in FIG. 2E, spot diagram 266 can correspond to light rays 226 with a 0 degree angle of incidence, spot diagram 268 can correspond to light rays 228 with a 5 degree angle of incidence, spot diagram 270 can correspond to light rays 230 with a 10 degree angle of incidence, spot diagram 272 can correspond to light rays 232 with a 15 degree angle of incidence, spot diagram 274 can correspond to light rays 234 with a 20 degree angle of incidence, and spot diagram 276 can correspond to light rays 236 with a 25 degree angle of incidence. In the illustrated spot diagrams 266, 268, 270, 272, 274, 276, the dots represent the location on the focal plane (e.g., focal plane 238 shown in FIG. 2C) of rays passing through different portions of the meta-lens 224. As shown in the spot diagram 266, the hyperbolic meta-lens 224 can provide an ideal focus at 0 angle of incidence. However, as shown in spot diagrams 268, 270, 272, 274, 276 as the angle of incidence increases, the amount of spread also increases. As shown in spot diagram 276, some light rays with an angle of incidence of 25 degrees can arrive at the focal plane over 100 μm from the ideal focal point on the focal plane.

FIG. 2F illustrates spot diagrams at the focal plane for the light rays 246, 248, 250, 252, 254, 256 passing through meta-lens 244 as shown in FIG. 2D. In the spot diagrams 286, 288, 290, 292, 294, 296 the plotted grids represent an area with dimensions 20 μm×20 μm and the center of each grid can correspond to the center of the focal plane (e.g., focal plane 258 shown in FIG. 2D). In the illustration of FIG. 2F, each of the spot diagrams 286, 288, 290, 292, 294, 296 includes a circle representing the diffraction limit for focusing the incident light. For example, circle 298 shows the diffraction limit illustrated on the spot diagram 286. Each of the remaining spot diagrams 288, 290, 292, 294, 296 include a similar circle (not labeled). As shown in FIG. 2F, spot diagram 286 can correspond to light rays 246 with a 0 degree angle of incidence, spot diagram 288 can correspond to light rays 248 with a 5 degree angle of incidence, spot diagram 290 can correspond to light rays 250 with a 10 degree angle of incidence, spot diagram 292 can correspond to light rays 252 with a 15 degree angle of incidence, spot diagram 294 can correspond to light rays 254 with a 20 degree angle of incidence, and spot diagram 296 can correspond to light rays 256 with a 25 degree angle of incidence. In the illustrated spot diagrams 286, 288, 290, 292, 294, 296, the dots represent the location on the focal plane (e.g., focal plane 258 shown in FIG. 2D) of rays passing through different portions of the meta-lens 244. As shown in the spot diagram 286, the optimized lens 244 can provide an ideal focus at 0 angle of incidence. As shown in spot diagrams 288, 290, 292, 294, 296 as the angle of incidence increases, the amount of spread increases by only a small degree when compared to the spot diagrams hyperbolic lens spot diagrams illustrated 266, 268, 270, 272, 274, 276 in FIG. 2E. As shown, in spot diagrams 288, 290, 292, 294, 296, the rays passing through the optimized meta-lens 244 can be focused within a 10 μm radius in any direction from the ideal focal point on the focal plane.

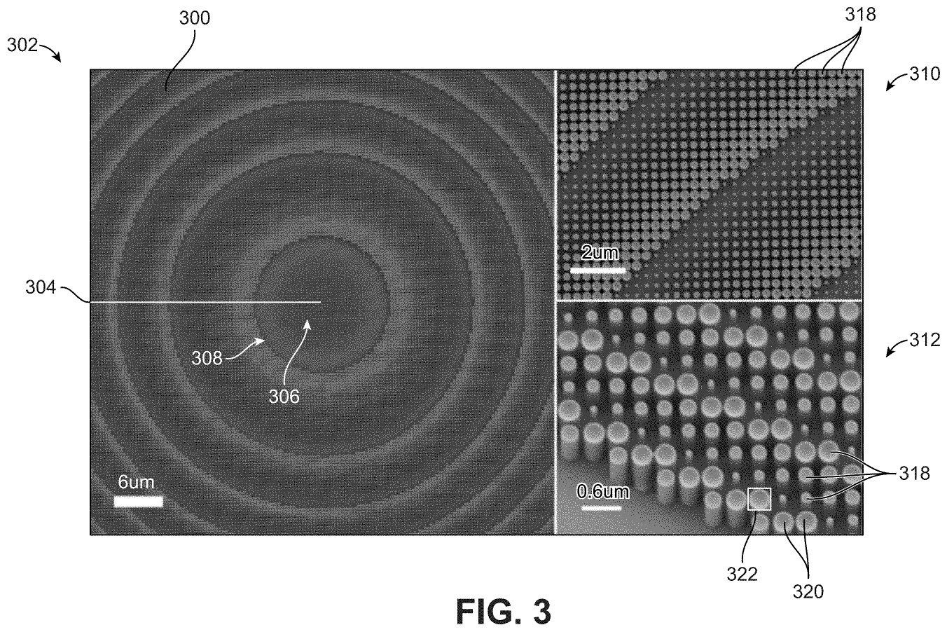

FIG. 3 illustrates example magnified portions of a meta-lens 300 illustrating a pattern of unit cells with varying pillar diameters. In one illustrative example, the pillar sizes of meta-lens 300 can correspond to the example meta-lens illustrated in plot 212 shown in FIG. 2B. As illustrated in FIG. 3, a low magnification level view 302 of the meta-lens 300 shows that the pattern of pillars 318 (which can correspond to pillars 118 shown in FIG. 1C and FIG. 1D above) of the meta-lens 300 can have a radially symmetric pattern extending from the center of the meta-lens 300 to the periphery of the meta-lens 300. In the illustration of FIG. 3, a line segment 304 extending radially from the center 306 of the meta-lens 300 is drawn. As shown in the plot 212 of FIG. 2B, near the center 306 of the meta-lens 300, the diameter of the pillars 318 can have a maximum value. In one illustrative example, the diameter of the pillars 318 at the center of the meta-lens 300 can be approximately equal to or slightly smaller than the width U of a unit cell (e.g., unit cell 114 as shown in FIG. 1C and FIG. 1D). Moving away from the center 306 of the meta-lens 300, the pillar size can decrease (providing a correspondingly smaller phase shift) relative to the pillars at the center 306 of the meta-lens until a phase reset point 308 (e.g., phase reset points 218 shown in FIG. 2B) is reached. At the phase reset point 308, the size of the pillars 318 can be reset to the largest diameter. In some cases, the varying diameters of the pillars 318 can create a ring-like appearance. The medium magnification level 310 and high magnification level 312 further illustrate the appearance of the pillars within the unit cells. As illustrated, the pillars 318 can be centered on a common pitch and large pillars 320 can have a diameter slightly smaller than the width U of a unit cell 322 (depicted as a white square).

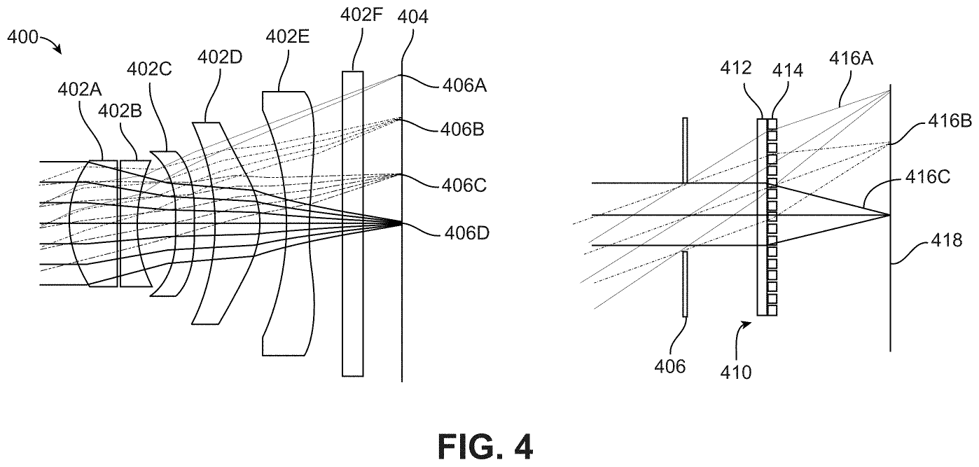

FIG. 4 illustrates lateral views of a compound lens 400 and a corresponding meta-lens 410 that can have similar optical characteristics. In the illustration of FIG. 4, the compound lens 400 includes lens elements 402A, 402B, 402C, 402D, 402E, and a sensor cover glass 402F that when stacked together can provide desired optical characteristics for a particular application. For example, the compound lens 400 can be designed with a particular target focal range, a wide angle field of view, and desired upper limit amounts of spherical aberration and chromatic aberration, among other characteristics. In the compound lens 400, the various optical elements 402A, 402B, 402C, 402D, 402E, 402F can each refract incoming light rays 406A, 406B, 406C, 406D in different ways such that the overall effect of the optical elements 402A, 402B, 402C, 402D, 402E, 402F, when stacked together, provides the desired optical performance. In the illustrated example, the compound lens 400 can operate to focus the incoming light rays 406A, 406B, 406D, 406D at the focal plane 404. In some examples, an optical sensor (also referred to as an image sensor, image detector, or light sensitive device herein) can be positioned at the focal plane 404 to detect the incoming light. Because multiple elements can be required to achieve the desired characteristics of the compound lens 400, the compound lens can add significant height, weight, and/or cost to a device using the compound lens 400 (e.g., a mobile device). In some cases, a device may have more than one camera as well as other optical sensors, each of which may require multiple separate compound lenses.

In some cases, a meta-lens 410 can be configured to perform with similar optical characteristics to the compound lens 400. In some implementations, a single layer meta-lens 410 can provide the desired optical characteristics for an imaging system (e.g., a camera, a range imager, or the like). In such cases, the meta-lens 410 can provide substantial savings in weight and thickness relative to the compound lens 400. The meta-lens 410 can include a substrate 412 and pillars 414 (e.g., pillars 118 shown in FIG. 1A, FIG. 1C and FIG. 1D). In some cases, light rays 416A, 416B, and 416C can arrive at the meta-lens 410 from different angles after passing through an aperture 406. As illustrated in FIG. 4, the meta-lens 410 can focus the light at a focal plane 418. In some examples, an optical sensor can be positioned at the focal plane 418 to detect the incoming light. In some cases, meta-lens 410 structures can be fabricated with an electron beam (e-beam) lithography prospects. In some aspects, e-beam lithography can be a costly and time consuming process because e-beam lithography individually draws the desired structure for each meta-lens. Accordingly, the fabricating meta-lenses in large quantities using e-beam lithography can become prohibitively expensive and time consuming.

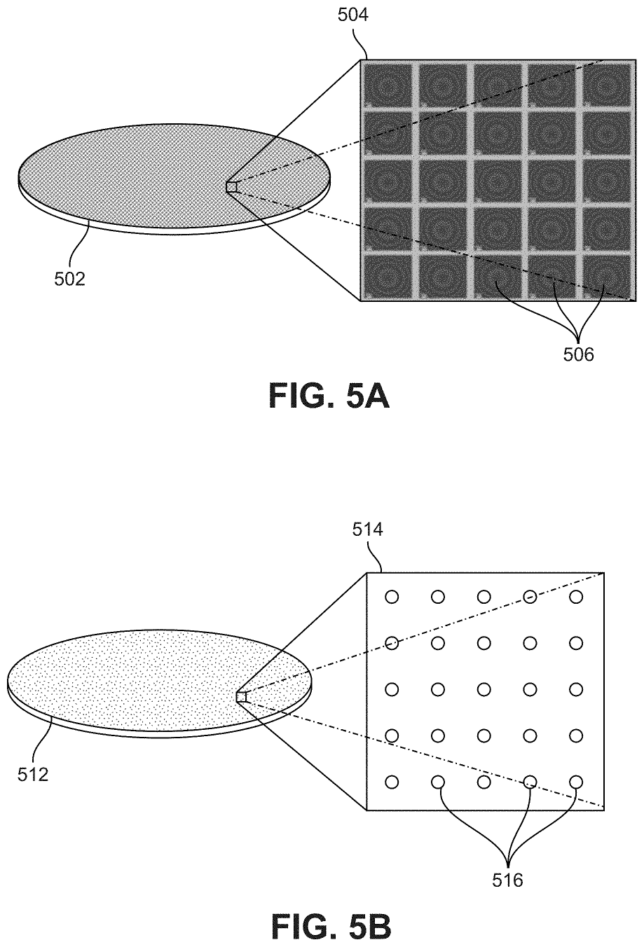

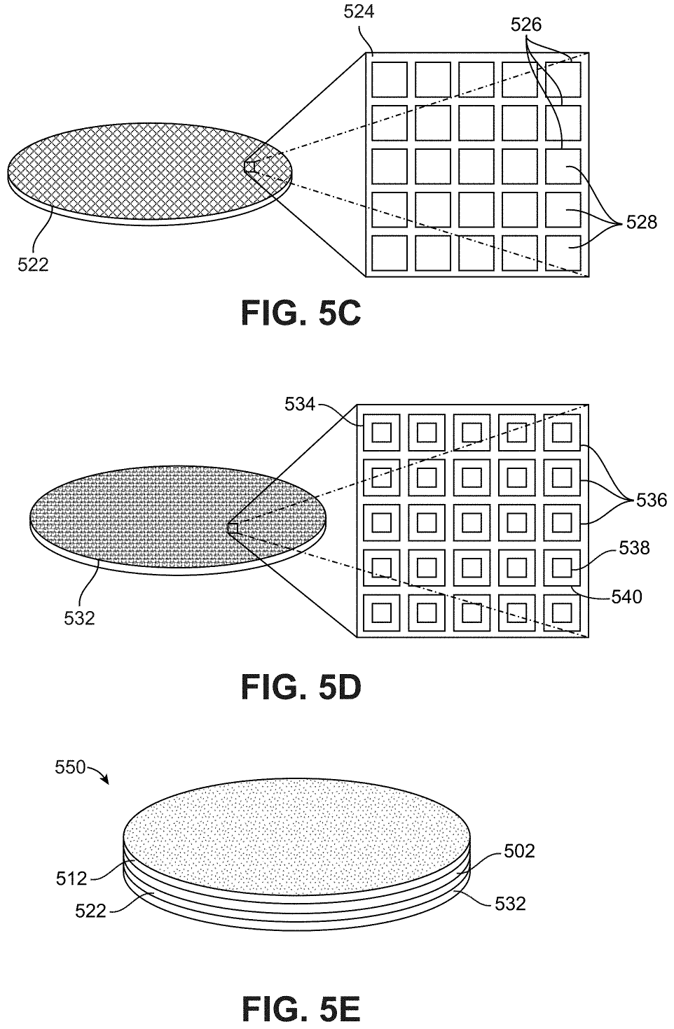

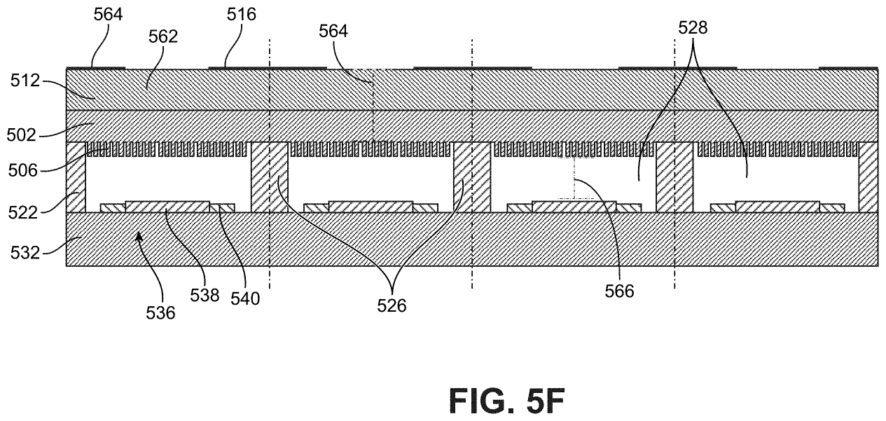

FIG. 5A through FIG. 5E illustrate an example process for manufacturing and assembling a wafer stackup 550 using a wafer stacking technique. FIG. 5A illustrates a perspective view of a meta-lens wafer 502 with a magnified portion 504 depicting an array of meta-lenses 506 fabricated on the meta-lens wafer 502. In some cases, each of the meta-lenses 506 can correspond to any one of the meta-lens 130 shown in FIG. 1B, meta-lens 300 shown in FIG. 3, meta-lens 410 shown in FIG. 4, or any other meta-lens. In some cases, the meta-lens wafer 502 can include a silicon wafer. For example, the meta-lens wafer 502 can include a double-side polished silicon wafer. In some cases, the meta-lenses 506 can be fabricated on a silicon wafer using semiconductor manufacturing techniques such as photolithography, reactive ion etching (RIE) and the like. In some cases, the meta-lens wafer 502 can include a material that is transparent to the visible light spectrum (e.g., glass). In some cases, pillars (e.g., pillars 118 shown in FIG. 1A) of the meta-lenses 506 can be fabricated using materials that are transparent to the visible light spectrum. In one illustrative example, a high refractive index material such as Titanium Dioxide (TiO₂) can be used to form the pillars.

FIG. 5B illustrates a perspective view of an aperture wafer 512 with a magnified portion 514 depicting multiple apertures 516 fabricated on the meta-lens wafer. In some cases, the aperture wafer can include a silicon wafer. In some cases, the aperture wafer 512 can include a material that is transparent to the visible light spectrum (e.g., glass). In some cases, the multiple apertures 516 can be fabricated by depositing an opaque material on the surface of the aperture wafer 512. In some cases, the opaque material can include any material that is opaque at the wavelength (or range of wavelengths) for a particular optical detection application. Example optical detection applications can include visible light applications, near infra-red (NIR) applications, SWIR applications, or the like.

FIG. 5C illustrates a perspective view of spacer wafer 522 with a magnified portion 524 depicting a pattern of spacer structures 526 fabricated on the spacer wafer 522. In some cases, the spacer wafer 522 can include a silicon wafer. In some cases, the spacer wafer 522 can include a material that is transparent to the visible light spectrum (e.g., glass). In some cases, the spacer structures 526 can be fabricated from a dielectric material (e.g., polyimide). In some cases, each of the spacer structures 526 can have dimensions and pitch equal to the dimensions and pitch of the meta-lenses 506 shown in FIG. 5A. In some cases, the spacer structures 526 can include spacer material in a border region that corresponds to the outside border of the meta-lenses 506. In some cases, each spacer structure 526 can form a border around a corresponding meta-lens 506 on the meta-lens wafer 502. In some cases, each spacer structure 526 can form a border around a corresponding optical sensor 536 of the optical sensor wafer 532.

FIG. 5D illustrates a perspective view of an optical sensor wafer 532 with a magnified portion 534 depicting optical sensors 536 disposed on the optical sensor wafer 532. In some cases, the optical sensor wafer 532 can include a silicon wafer. In some cases, the optical sensors 536 can be fabricated with a GeSi CMOS process on the silicon wafer. In some cases, the optical sensors 536 can include a photosensitive region 538. In some cases, the optical sensors 536 can include additional circuitry 540. In some cases, the additional circuitry 540 can include readout circuitry that can be used to read the signals captured by the optical sensors.

FIG. 5E illustrates a wafer stackup 550 comprising the aperture wafer 512, the meta-lens wafer 502, the spacer wafer 522 and the optical sensor wafer 532. In some cases, the aperture wafer 512 can be coupled to a first side of the meta-lens wafer 502. In some cases, the meta-lenses 506 on the meta-lens wafer 502 can be disposed on a second side of the meta-lens wafer 502 opposite the first side. In some cases, a distance between each aperture of the multiple apertures 516 and a corresponding meta-lens 506 of the meta-lenses 506 can be equal to a sum of a thickness of the aperture wafer 512 and a thickness of the meta-lens wafer 502. In some applications, a distance between the multiple apertures 516 and the meta-lenses 506 can affect optical performance, such as depth of field. In some cases, the aperture wafer 512 and/or the meta-lens wafer 502 can be polished to attain a desired thickness based on a desired distance between the apertures 516 and the meta-lenses 506.

In some cases, a first side of the spacer wafer 522 can be coupled to a second side of the meta-lens wafer 502 (e.g., the side having the meta-lenses 506 disposed thereon). In some examples, a second side of the spacer wafer 522 can be coupled to the optical sensor wafer 532. In some cases, the spacer structures 526 on the spacer wafer 522 can be designed to border the meta-lenses 506 on the first side of the spacer wafer 522. In some cases, the spacer structures 526 on the spacer wafer 522 can be designed to border the optical sensors 536. In some cases, the meta-lenses 506 and the optical sensors can be positioned within cavities 528 in the spacer structures. In some cases, a desired distance between the meta-lenses 506 and the optical sensors 536 can be equal to the back focal length (BFL) of the meta-lenses 506. In some cases, a thickness of the spacer structures 526 can be used to separate the meta-lenses 506 and the optical sensors 536 by the focal length of the meta-lenses 506. In some cases, the wafer stackups can create an array of meta-lenses 506, apertures 516, spacer structures 526, and optical sensors 536 having a common pitch. In some cases, by aligning the wafers 502, 512, 522, and 532, modules each comprising a meta-lens, an aperture, a spacer structure, and an optical sensor can be formed. In some cases, each aperture of the apertures 516 can be positioned over a corresponding meta-lens of the meta-lenses 506. In some cases, the meta-lens, aperture, and optical sensor for each meta-lens module can be aligned to an optical axis. For example, a meta-lens, an aperture, and a photosensitive region of an optical sensor can each be centered on the optical axis of the meta-lens 506. In some cases, the wafers 502, 512, 522, and 532 can be mechanically coupled using an epoxy. In some cases, an epoxy that is transparent to the relevant wavelengths of light can be selected. For example, a liquid optically clear adhesive (LOCA) can be used for visible light, NIR, and SWIR applications. In some cases, the epoxy can be disposed only in regions of the wafers 502, 512, 522, and 532 where light does not need to pass through.

FIG. 5F illustrates a cross-sectional view of the wafer stackup 550 shown in FIG. 5E. As shown in the illustration, an aperture 562 of the multiple apertures 516 can be formed as an opening in the opaque layer 564 disposed on the aperture wafer 512. In some cases, during the wafer stacking process described with respect to FIG. 5E, the aperture wafer 512 can be coupled to the meta-lens wafer 502. In some cases, the combined thickness of the aperture wafer 512 and the meta-lens wafer 502 can create a spacing 660 between apertures 516 on the aperture wafer 512 and corresponding meta-lenses 506 on the meta-lens wafer 502. In some implementations, spacer structures 526 of the spacer wafer 522 can include cavities 528. In some cases, the meta-lenses 506 and the optical sensors 536 can be contained within the cavities 528. In some cases, a height of the spacer structures 526 can be configured to provide spacing 566 that places each optical sensor 536 at a focal plane of a corresponding meta-lens 506. In some cases, the optical sensors 536 can comprise a photosensitive region 538 and additional circuitry 540 as described above. In some cases, the photosensitive region 538 and the additional circuitry 540 can be fabricated on a surface of the optical sensor wafer 532.

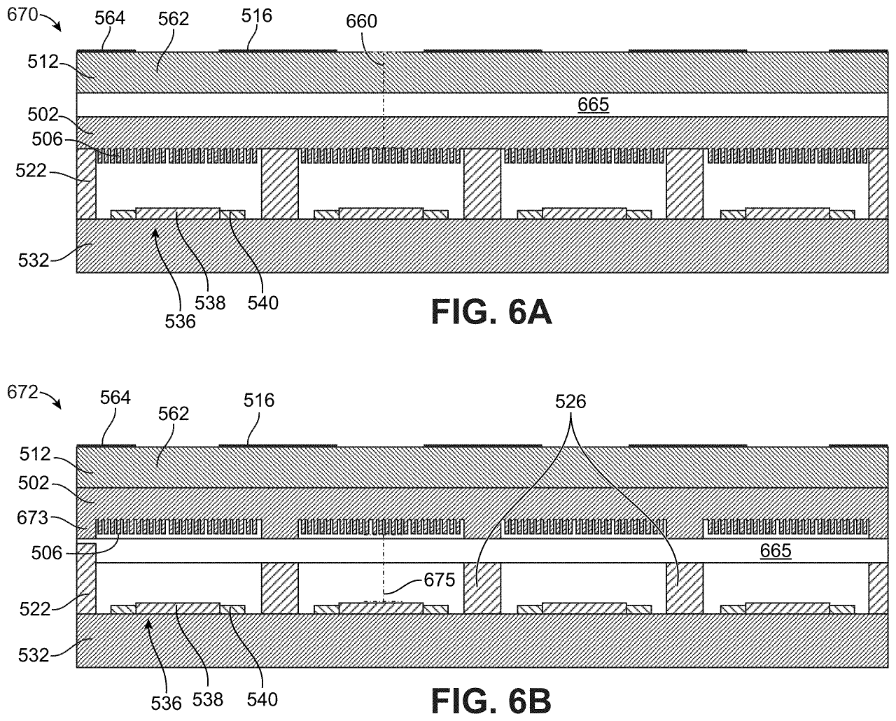

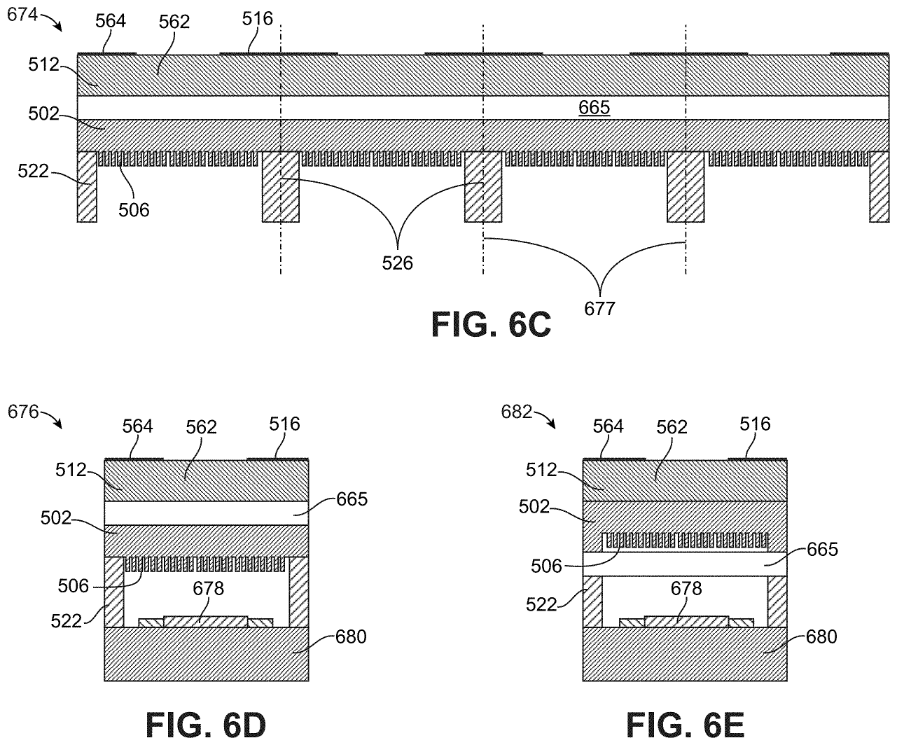

FIG. 6A through FIG. 6E illustrate cross-sectional views of different example wafer stacking configurations. The illustrations of FIG. 6A through 6E include components labeled with reference numbers that are described above with respect to FIG. 5A through FIG. 5F and the components shown in FIG. 6A through 6E can be similar to and perform similar functions to identically numbered components in FIG. 5A through FIG. 5F. FIG. 6A illustrates a wafer stackup 670 that includes an optical filter 665. In some cases, the optical filter 665 can be a band-pass optical filter. In one illustrative example, the optical filter 665 can be configured to pass light at the SWIR wavelengths (e.g., in a narrow band around 1400 nm) while attenuating light at all other wavelengths. In the example of FIG. 6A, the optical filter 665 is disposed between the aperture wafer 512 and the meta-lens wafer 502. In such a configuration, a spacing 660 between the apertures 516 and the optical sensors 536 can be equal to the combined thickness of the aperture wafer 512, the optical filter 665, and the meta-lens wafer 502.

FIG. 6B illustrates an example wafer stackup 672 that includes the optical filter 665 disposed between the meta-lens wafer 502 and the spacer wafer 522. In some cases, placing the optical filter 665 after the meta-lens wafer 502 in the stackup 672 can cause the rays of light to be normally incident on the optical filter 665. Accordingly, in some cases, placing the optical filter 665 after the meta-lens wafer 502 in the stackup 672 can reduce blue-shift of the optical filter 665, and a narrower band optical filter 665 can be used. In some cases, the meta-lens wafer 502 can include an additional spacer structure 673 that can couple to the optical filter 665 to provide spacing between the pillars (e.g., pillars 118 shown in FIG. 1A, FIG. 1C, and FIG. 1D above) of the meta-lenses 506 and the optical filter 665. In some cases, the additional spacer structures 673 can be fabricated on the meta-lens wafer as part of the same manufacturing process used to fabricate the meta-lenses 506 on the meta-lens wafer. In some cases, the distance 675 between the meta-lenses 506 and the optical sensors 536 can be a sum of the height of the additional spacer structures 673, the optical filter 665, and the spacer structures 526 of the spacer wafer 522. In the example configuration of FIG. 6B, the distance 675 between the meta-lenses 506 and corresponding optical sensors 536 can be configured to be equal to the back focal length of the meta-lenses 506.

FIG. 6C illustrates an example wafer stackup 674. The wafer stackup 674 can include an aperture wafer 512, an optical filter 665, a meta-lens wafer 502, and a spacer wafer 522 in a similar configuration to the wafer stackup 670 shown in FIG. 6A. In the example wafer stackup 674, the optical sensor wafer 532 can be omitted from the stackup 670. In some cases, the wafer stackup 674 can be used to fabricate meta-lens modules that can later be coupled individually to optical sensors. For example, individual meta-lens modules can be formed by dicing the wafer stackup 674 along dice lines 677.

FIG. 6D illustrates an example of a meta-lens camera module 676. As used herein, a meta-lens camera module can include any optical system that incorporates a meta-lens as a component. In some cases, the meta-lens camera module 676 can be formed by dicing the wafer stackup 670 shown in FIG. 6A. In some cases, the meta-lens camera module 676 can be formed by coupling the meta-lens modules described with respect to FIG. 6C with an optical detector 678 on a substrate 680.

FIG. 6E illustrates another example of a meta-lens camera module 682. In some cases, the meta-lens module 682 can be formed by dicing the wafer stackup 672 shown in FIG. 6B. In some examples, the meta-lens camera module 682 can be formed from a meta-lens module diced from a wafer stackup similar to the wafer stackup 672 that omits the optical sensor wafer 532. In such examples, the meta-lens camera module 682 can be formed by coupling the meta-lens module with an optical detector 678 on a substrate 680.

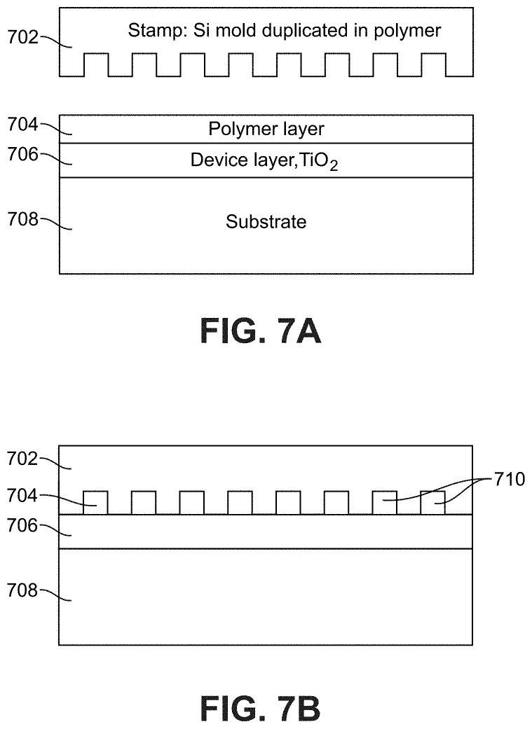

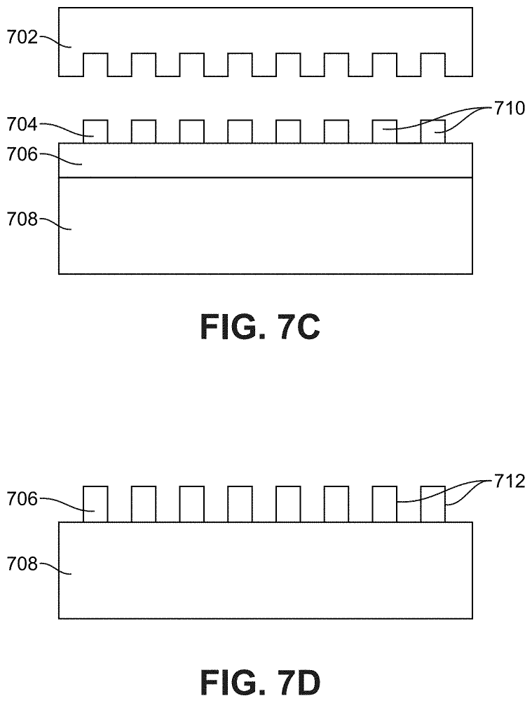

FIG. 7A through FIG. 7D illustrate an example nanoimprinting lithography process for manufacturing meta-lenses (e.g., a meta-lens wafer 502 shown in FIG. 5A). In the illustrated example, a mold can be formed from a meta-lens, such as a meta-lens manufactured using an e-beam lithography process on a silicon wafer as described above. In some cases, a mask or model can be formed using the meta-lens. In some cases, the mask of the meta-lens can be duplicated into an array of meta-lenses and formed into a stamp 702. In some cases, the stamp 702 can be used to transfer the pattern of the array of meta-lens to a device layer 706 disposed over a substrate 708. In some cases, the substrate 708 can be a material that is transparent to visible wavelength light, such as glass. In some cases, the device layer 706 can include a transparent material that can be used to form the pillars of meta-lenses on the substrate 708. In some cases, the device layer 706 can include a high refractive index material. For example, in some cases, the device layer 706 can include a material with a refractive index greater than 2. In some cases, the device layer 706 can include a material with a refractive index greater than 2.5. In some cases, the device layer 706 can include a material that is transparent to visible wavelength light. In one illustrative example, the device layer 706 can include Titanium Dioxide (TiO₂).

FIG. 7B illustrates an imprinting step of the process for manufacturing meta-lenses. In some cases, the stamp 702 can be pressed against the polymer layer 704 to create a negative pattern 710 of the stamp 702 impressed into the polymer layer. In some cases, the negative pattern 710 can also be referred to as a nanoimprint. FIG. 7C illustrates the negative pattern 710 disposed on top of the device layer 706 after removal of the stamp 702. In some cases, the polymer layer 704 can be heated until it becomes soft, which can allow the stamp 702 to deform the polymer layer 704. In some cases, after the heat is removed, the polymer can be cooled until hardened. In some cases, after the polymer 704 is cooled, stamp 702 can be removed, resulting in the negative pattern 710 imprinted into the polymer layer 704. In some cases, after removal of the stamp 702, the polymer layer 704 can be exposed to light and/or baked to cause the polymer material to harden and become resistant to etching. After removal of the stamp 702, the device layer 706 can be etched (e.g., via wet etching, dry etching, RIE or other etching techniques), and portions of the device layer 706 that are not covered and protected by the negative pattern 710 can be etched away and removed. After etching of the device layer is completed, the remaining polymer layer 704 can be removed. For example, the polymer layer 704 can be removed by organic stripping, inorganic stripping, dry stripping, or any other suitable technique.

FIG. 7D illustrates a meta-lens pattern 712 etched into the device layer 706 after removal of the polymer layer 704. In some cases, a single meta-lens can be formed on the substrate 708. In some cases, an array of meta-lenses can be formed in the device layer 706. The example process illustrated by FIG. 7A through FIG. 7D can be referred to as a nanoimprint lithography process. The nanoimprint lithography process can be used as an alternative to fabricating meta-lenses when techniques for fabricating meta-lenses using semiconductor fabrication techniques. In some cases, the meta-lenses fabricated using the nanoimprint lithography technique can be included in a wafer stackup similar to the wafer stackups illustrated in FIG. 5A through FIG. 5F and FIG. 6A through FIG. 6E.

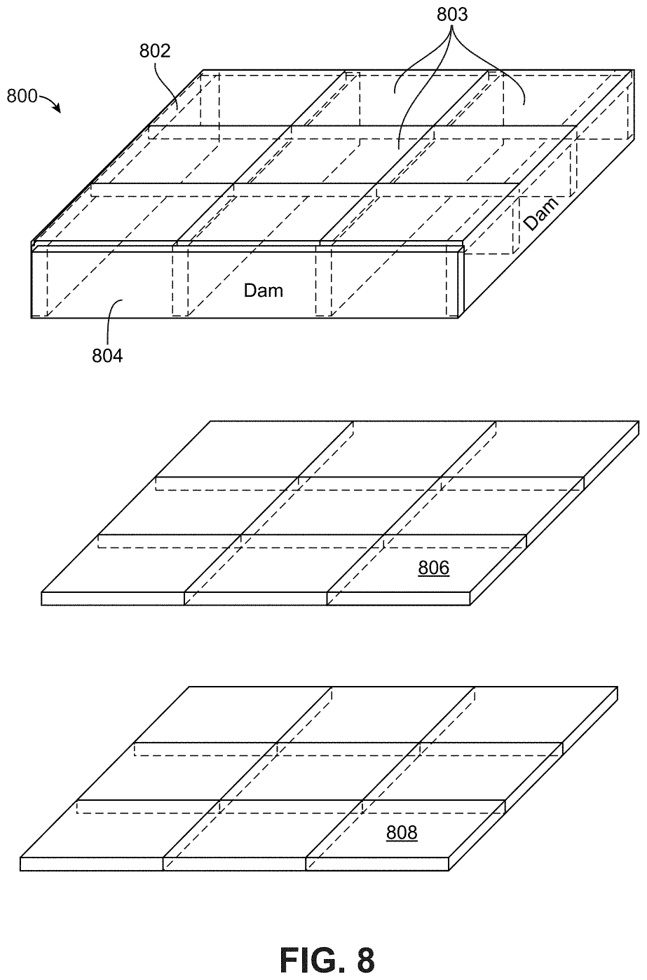

FIG. 8 illustrates another example wafer stackup 800 that can be used to fabricate optical systems that include meta-lenses (e.g., meta-lens camera modules). In some cases, a meta-lens wafer 802 (e.g., meta-lens wafer 502 shown in FIG. 5A and FIG. 5E above) can include an array of meta-lenses 803. In some cases, rather than utilizing a separate spacer wafer (e.g., spacer wafer 522 shown in FIG. 5C and FIG. 5E above), a spacer structure 804 can be fabricated directly on the meta-lens wafer 802. In the illustrated example of FIG. 8, the spacer structure 804 can be configured as a dam structure, forming four walls around each meta-lens disposed on the meta-lens wafer 802. In some cases, the spacer structure 804 can be similar to and perform similar functions as the spacer structures 526 shown in FIG. 6A through FIG. 6E. The wafer stackup 800 can also include a detector component wafer 806 and a control and processing component wafer 808. As discussed above, the meta-lens wafer 802, detector component wafer 806, and the control and processing component wafer 808 can be assembled in a wafer stacking technique. Although not shown in FIG. 8, the wafer stackup 800 can also include an aperture wafer (e.g., aperture wafer 512 shown in FIG. 5B) and/or an optical filter (e.g., optical filter 665 shown in FIG. 6A through FIG. 6E). In some cases, supplemental spacer structures (not shown) can be disposed on the detector array to provide separation between an optical filter and the detector array. In some cases, the height of the spacer structure 804 can be adjusted to ensure that the detector components included in the detector component wafer 806 are separated from the meta-lens wafer 802 by the focal distance of corresponding meta-lenses 803 on the meta-lens wafer 802.

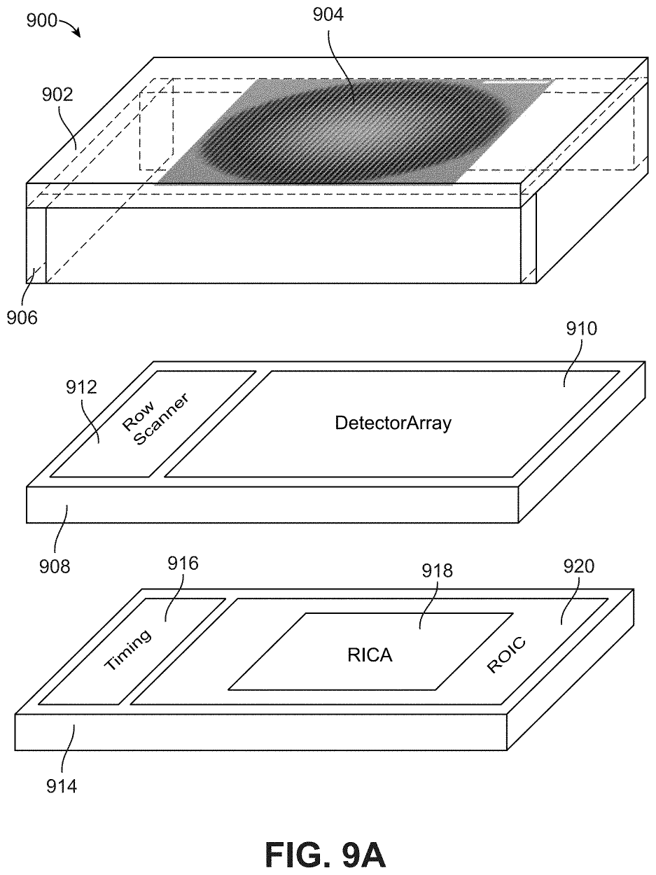

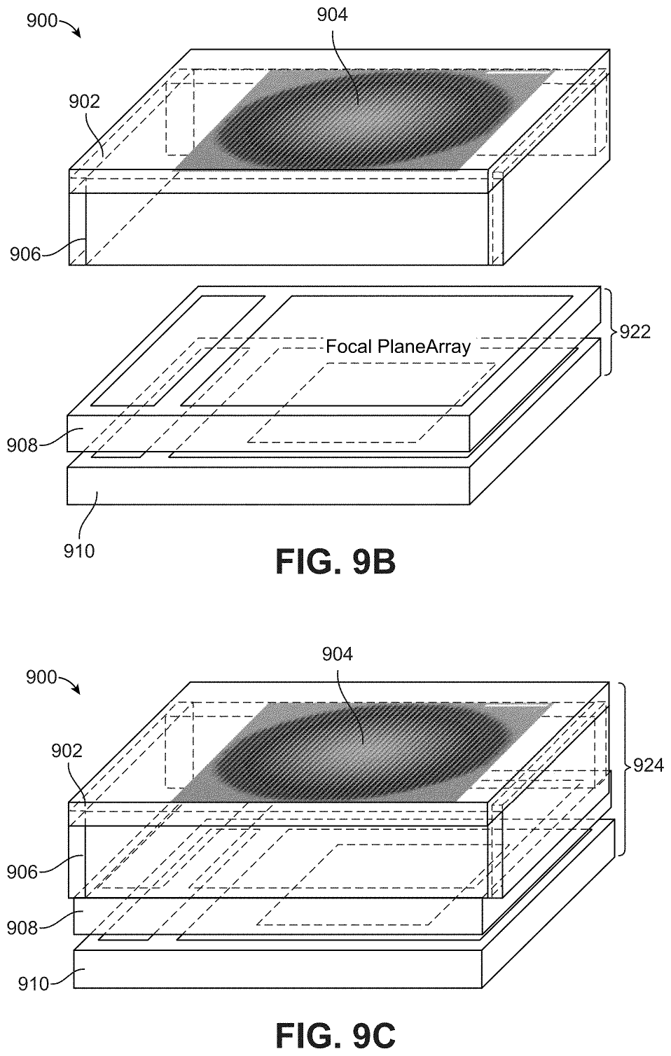

FIG. 9A through FIG. 9C illustrate perspective views of an example wafer stackup 900 that can be used to fabricate meta-lens camera modules. FIG. 9A illustrates a stackup 900 that includes a meta-lens 904 disposed on a substrate 902, a dam structure 906 disposed on the substrate 902, a detector component 908, and a control and processing component 914. In some cases, the dam structure 906 can correspond to the spacer structure 804 shown in FIG. 8. In some cases, a height of the dam structure 906 can be configured to separate the meta-lens 904 from the detector component 908 to place the detector component 908 at the focal plane of the meta-lens 904.

In the illustrated example of FIG. 9A, the detector component 908 can include a detector array 910 and a row scanner 912. In some cases, the detector array 910 can include photosensitive elements that can detect light with a particular wavelength or range of wavelengths. For example, in some cases, the detector array can include photosensitive elements that can detect light in the SWIR wavelength. In one illustrative example, the photosensitive elements can detect light within a narrow band centered around approximately 1400 nm wavelength. In some aspects, the detector array 910 can include photosensitive elements that can detect visible light. In some cases, the row scanner 912 can be configured to scan the photosensitive elements in a scan pattern to read electrical signals (e.g., a voltage, current, or the like) that correspond to an amount of light detected by each photosensitive element during a particular time period (e.g., an exposure period).

In the illustrated example of FIG. 9A, the control and processing component 914 can include a timing control component 916, a reconfigurable instruction cell array (RICA) 918, and a readout integrated circuit (ROIC) 920. In some cases, the timing control component 916 can provide control signals to one or more components of the meta-lens stackup 900. For example, the timing control component can provide timing signals to control operations of the row scanner 912, the ROIC 920, and/or any other components included in the meta-lens stackup 900. In some aspects, the timing control component 916 can further provide timing signals to other components in a device that incorporates the meta-lens stackup 900.

In some cases, RICA 918 can be used to perform local image processing operations without requiring transferring image data over a bus to a processing unit. In some cases, the RICA can generate depth maps, stitch together multiple frames (or portions of frames) of image data, generate composite images from multiple captured images (or portions of images), as well as performing other image processing operations. As described above, in some cases, all of the components that form the stackup 900 can be fabricated using a semiconductor manufacturing process and assembled in a single wafer stacking process.

FIG. 9B and FIG. 9C illustrate example assembly steps that can be used to fabricate the meta-lens stackup 900. In the illustration of FIG. 9B, detector component 908 and the control and processing component 914 can be coupled together both mechanically and electrically to form a sensor chip 922. In some cases, electrical signals can be transmitted and received between the detector component 908 and the control and processing component 914 via the electrical connections. FIG. 9C illustrates the substrate 902 assembled together with the sensor chip 922 to form a meta-lens camera module 924. Although not shown, the meta-lens camera module 924 can also include an aperture, an optical filter and/or additional spacer structures as described herein. For example, supplemental spacer structures (not shown) can be disposed on the detector component 908 (or on a substrate that includes the detector component 908) to provide separation between an optical filter and the detector component. In such an example, the height of the dam structure 906 can be adjusted (e.g., reduced by the thickness of the supplemental spacer structures and the optical filter) to ensure that the detector component 908 is separated from the meta-lens 904 by the focal distance of the meta-lens 904.

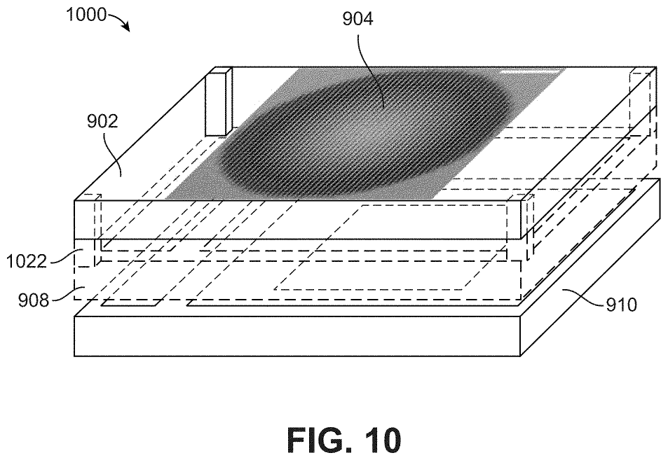

FIG. 10 illustrates a perspective view of an example meta-lens stackup 1000. The meta-lens stackup 1000 can be identical to the meta-lens stackup 900 described with respect to FIG. 9A through 9C, except that dam structure 906 shown in FIG. 9A through 9C can be replaced with a pillar structure 1022 disposed on the substrate 902.

As noted above, the wafer stacking techniques described herein can allow for large scale fabrication of meta-lenses, meta-lens modules, and meta-lens camera modules. For applications where silicon is transparent to the relevant wavelengths of light, meta-lenses can be fabricated on silicon wafers using standard semiconductor manufacturing techniques. Additional components such as apertures (e.g., apertures 516 shown in FIG. 5B), spacer structures (e.g., spacer structures 526 shown in FIG. 5C), and optical sensors (e.g., optical sensors 536 shown in FIG. 5D) can also be manufactured on silicon wafers using standard semiconductor techniques. In some cases, the wafers can be stacked and bonded (e.g., mechanically coupled) together to form a wafer stackup that includes an array of meta-lens camera modules (e.g., meta-lens camera module 676 shown in FIG. 6D or meta-lens camera module 682 shown in FIG. 6E). The array of meta-lens camera modules can be diced from the wafer stackup into individual meta-lens cameras.

As also noted above, in some cases, silicon may not be transparent to the relevant optical wavelengths for an application. For example, silicon is not transparent to visible light. In such cases, a nanoimprinting technique can be used to fabricate meta-lenses on substrate that is transparent to the relevant wavelength(s) of light (e.g., visible light). For example, in some cases, meta-lenses can be fabricated on a glass substrate. Similarly, apertures and spacer structures can be formed on glass substrates, and a similar stacking process can be used to assemble meta-lens camera modules suitable for visible light wavelengths, or any other suitable that is transparent to the relevant wavelength(s) of light for the particular application.

Furthermore, in some cases, a separate spacer wafer may not be required, and instead spacer structures can be formed directly on the meta-lens wafer or substrate. In some cases, spacer structures can also be formed on the optical sensor wafer (e.g., optical sensor wafer 532). In some cases, additional layers, such as optical filters, can be included in the stackup. Although many of the examples provided above describe wafer stackups that includes a single meta-lens and/or meta-lens wafer, in some cases, two or more meta-lenses and/or meta-lens wafers can be stacked to form doublet lenses and/or a compound lenses without departing from the scope of the present disclosure.

In some cases, the optical sensor wafer (e.g., optical sensor wafer 532 shown in FIG. 5D) can be omitted from a meta-lens stackup, and meta-lens modules can be fabricated. In such cases, the meta-lens modules can be diced from the wafer stackup and individually coupled to optical sensors. In some cases, meta-lens modules can allow for more flexible use of meta-lenses with different optical sensors.

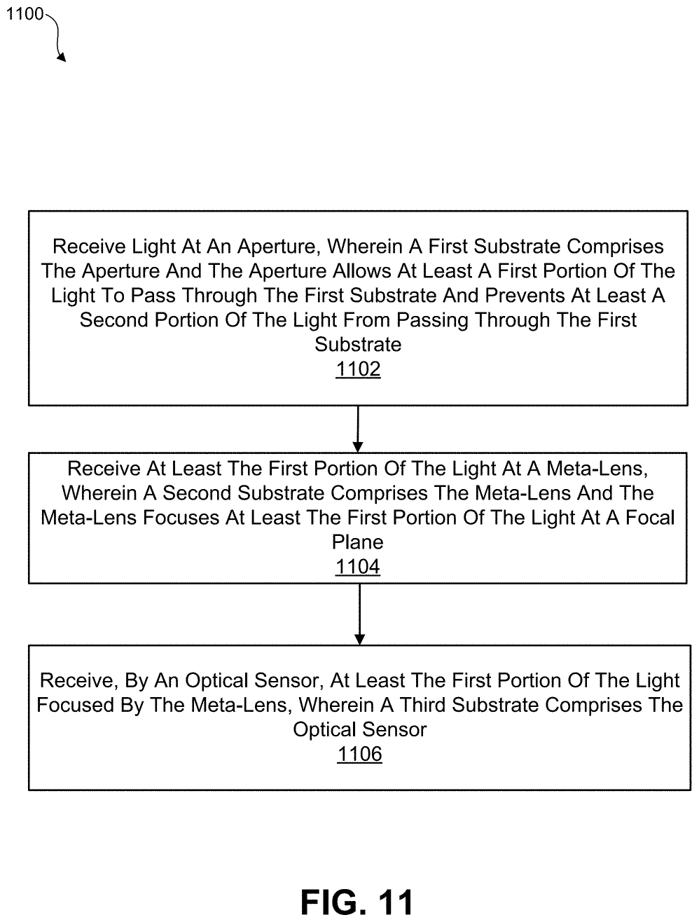

FIG. 11 is a flow diagram illustrating an example of a process 1100 of assembling a wafer stackup. At block 1102, the process 1100 includes receiving light at an aperture (e.g., apertures 222, 242 shown in FIG. 2C and FIG. 2D and/or apertures 516 shown in FIG. 5F). In some cases, a first substrate (e.g., aperture wafer 512 shown in FIG. 5A and FIG. 5E) includes the aperture. In some cases, the first substrate can include a silicon material. In some cases, the first substrate can include a double-side polished silicon material. In some cases, the first substrate can include a material transparent to visible light (e.g., glass). In some examples, the aperture allows at least a first portion of the light to pass through the first substrate and prevents at least a second portion of the light from passing through the first substrate.

At block 1104, the process 1100 includes receiving at least the first portion of the light at a meta-lens (e.g., meta-lens 130 shown in FIG. 1B, meta-lenses 224, 244 shown in FIG. 2C and FIG. 2D, meta-lens 300 shown in FIG. 3). In some cases, a second substrate (e.g., meta-lens wafer 502 shown in FIG. 5A and FIG. 5E) includes the meta-lens. In some cases, the second substrate can include a silicon material. In some examples, the second substrate can include a double-side polished silicon material. In some cases, the second substrate can include a material transparent to visible light (e.g., glass). In some examples, the meta-lens focuses at least the first portion of the light at a focal plane (e.g., focal planes 238, 258 shown in FIG. 2C and FIG. 2D).

At block 1106, the process 1100 includes receiving at least the first portion of the light focused by the meta-lens by an optical sensor (e.g., optical sensors 536 shown in FIG. 5C and FIG. 5E, optical detector 678 shown in FIG. 6D). In some examples, in a third substrate (e.g., optical sensor wafer 532 shown in FIG. 5D and FIG. 5E) includes the optical sensor.

In some implementations, the first substrate, the second substrate, and the third substrate are mechanically coupled (e.g., as part of wafer stackup 550 shown in FIG. 5E, part of wafer stackups 670, 672, 674 shown in FIG. 6A through FIG. 6C, and/or part of meta-lens camera modules 676, 682 shown in FIG. 6D and FIG. 6E). In some examples, the meta-lens and the optical sensor can be separated by a separation equal to a focal length of the meta-lens. In some cases, a spacer structure (e.g., spacer structures 526 shown in FIG. 5C and FIG. 5E, additional spacer structures 673 shown in FIG. 6B, spacer structure 804 shown in FIG. 8, dam structure 906 shown in FIG. 9A through FIG. 9C, and/or pillar structure 1022 shown in FIG. 10) provides at least a portion of the separation.

In some implementations, the process 1100 further includes generating at least a portion of an image based on detecting the first portion of the light. In some cases, the process 1100 further includes receiving at least the portion of the image at a RICA. In some examples, a fourth substrate includes the RICA and the first substrate, the second substrate, the third substrate, and the fourth substrate are mechanically coupled. In some cases, the RICA is configured to perform one or more image processing operations on at least the portion of the image. For example, the RICA can generate a depth map based on at least the portion of the image, generate a composite image based on at least the portion of the image, and/or stitch together at least the portion of the image and at least a portion of another image.

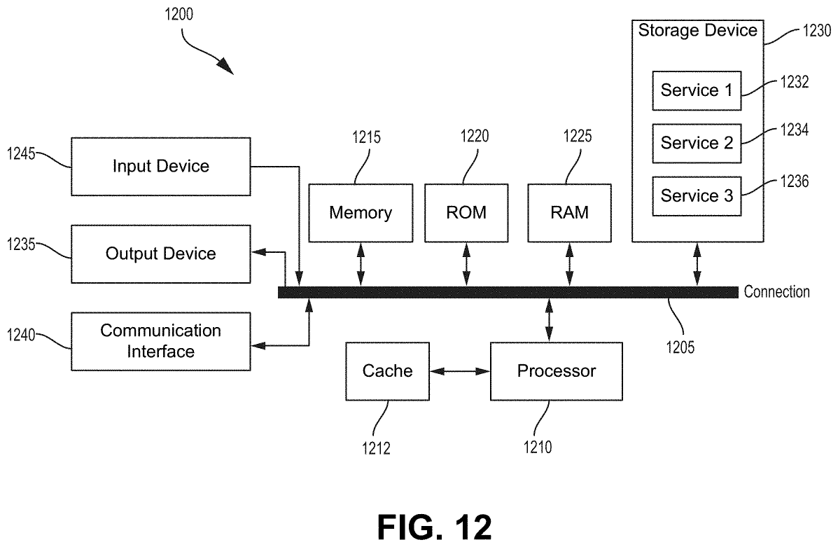

In some examples, the processes described herein (e.g., process 1100 and/or other process described herein) may be performed by a computing device or apparatus. For instance, the computing system 1200 shown in FIG. 12 can implement the one or more of the operations of the process 1100 of FIG. 11 and/or other processes described herein. In some examples, computing system 1200 shown in FIG. 12 can include and/or communicate with meta-lens camera modules (e.g., meta-lens camera module 676 shown in FIG. 6D and meta-lens camera module 682 shown in FIG. 6E) described herein.

The computing device can include any suitable device, such as a vehicle or a computing device of a vehicle (e.g., a driver monitoring system (DMS) of a vehicle), a mobile device (e.g., a mobile phone), a desktop computing device, a tablet computing device, a wearable device (e.g., a VR headset, an AR headset, AR glasses, a network-connected watch or smartwatch, or other wearable device), a server computer, a robotic device, a television, and/or any other computing device with the resource capabilities to perform the processes described herein, including the process 1100 and/or other process described herein. In some cases, the computing device or apparatus may include various components, such as one or more input devices, one or more output devices, one or more processors, one or more microprocessors, one or more microcomputers, one or more cameras, one or more sensors, and/or other component(s) that are configured to carry out the steps of processes described herein. In some examples, the computing device may include a display, a network interface configured to communicate and/or receive the data, any combination thereof, and/or other component(s). The network interface may be configured to communicate and/or receive Internet Protocol (IP) based data or other type of data.

The components of the computing device can be implemented in circuitry. For example, the components can include and/or can be implemented using electronic circuits or other electronic hardware, which can include one or more programmable electronic circuits (e.g., microprocessors, graphics processing units (GPUs), digital signal processors (DSPs), central processing units (CPUs), and/or other suitable electronic circuits), and/or can include and/or be implemented using computer software, firmware, or any combination thereof, to perform the various operations described herein.

The process 1100 illustrated as logical flow diagrams, the operation of which represents a sequence of operations that can be implemented in hardware, computer instructions, or a combination thereof. In the context of computer instructions, the operations represent computer-executable instructions stored on one or more computer-readable storage media that, when executed by one or more processors, perform the recited operations. Generally, computer-executable instructions include routines, programs, objects, components, data structures, and the like that perform particular functions or implement particular data types. The order in which the operations are described is not intended to be construed as a limitation, and any number of the described operations can be combined in any order and/or in parallel to implement the processes.

Additionally, the process 1100 and/or other process described herein may be performed under the control of one or more computer systems configured with executable instructions and may be implemented as code (e.g., executable instructions, one or more computer programs, or one or more applications) executing collectively on one or more processors, by hardware, or combinations thereof. As noted above, the code may be stored on a computer-readable or machine-readable storage medium, for example, in the form of a computer program comprising a plurality of instructions executable by one or more processors. The computer-readable or machine-readable storage medium may be non-transitory.

FIG. 12 is a diagram illustrating an example of a system for implementing certain aspects of the present technology. In particular, FIG. 12 illustrates an example of computing system 1200, which can be for example any computing device making up internal computing system, a remote computing system, a camera, or any component thereof in which the components of the system are in communication with each other using connection 1205. Connection 1205 can be a physical connection using a bus, or a direct connection into processor 1210, such as in a chipset architecture. Connection 1205 can also be a virtual connection, networked connection, or logical connection.

In some embodiments, computing system 1200 is a distributed system in which the functions described in this disclosure can be distributed within a datacenter, multiple data centers, a peer network, etc. In some embodiments, one or more of the described system components represents many such components each performing some or all of the function for which the component is described. In some embodiments, the components can be physical or virtual devices.

Example system 1200 includes at least one processing unit (CPU or processor) 1210 and connection 1205 that couples various system components including system memory 1215, such as read-only memory (ROM) 1220 and random access memory (RAM) 1225 to processor 1210. Computing system 1200 can include a cache 1212 of high-speed memory connected directly with, in close proximity to, or integrated as part of processor 1210.

Processor 1210 can include any general purpose processor and a hardware service or software service, such as services 1232, 1234, and 1236 stored in storage device 1230, configured to control processor 1210 as well as a special-purpose processor where software instructions are incorporated into the actual processor design. Processor 1210 may essentially be a completely self-contained computing system, containing multiple cores or processors, a bus, memory controller, cache, etc. A multi-core processor may be symmetric or asymmetric.

To enable user interaction, computing system 1200 includes an input device 1245, which can represent any number of input mechanisms, such as a microphone for speech, a touch-sensitive screen for gesture or graphical input, keyboard, mouse, motion input, speech, etc. Computing system 1200 can also include output device 1235, which can be one or more of a number of output mechanisms. In some instances, multimodal systems can enable a user to provide multiple types of input/output to communicate with computing system 1200. Computing system 1200 can include communications interface 1240, which can generally govern and manage the user input and system output. The communication interface may perform or facilitate receipt and/or transmission wired or wireless communications using wired and/or wireless transceivers, including those making use of an audio jack/plug, a microphone jack/plug, a universal serial bus (USB) port/plug, an Apple® Lightning® port/plug, an Ethernet port/plug, a fiber optic port/plug, a proprietary wired port/plug, a BLUETOOTH® wireless signal transfer, a BLUETOOTH® low energy (BLE) wireless signal transfer, an IBEACON® wireless signal transfer, a radio-frequency identification (RFID) wireless signal transfer, near-field communications (NFC) wireless signal transfer, dedicated short range communication (DSRC) wireless signal transfer, 802.11 Wi-Fi wireless signal transfer, wireless local area network (WLAN) signal transfer, Visible Light Communication (VLC), Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/5G/LTE cellular data network wireless signal transfer, ad-hoc network signal transfer, radio wave signal transfer, microwave signal transfer, infrared signal transfer, visible light signal transfer, ultraviolet light signal transfer, wireless signal transfer along the electromagnetic spectrum, or some combination thereof. The communications interface 1240 may also include one or more Global Navigation Satellite System (GNSS) receivers or transceivers that are used to determine a location of the computing system 1200 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 1230 can be a non-volatile and/or non-transitory and/or computer-readable memory device and can be a hard disk or other types of computer readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a compact disc read only memory (CD-ROM) optical disc, a rewritable compact disc (CD) optical disc, digital video disk (DVD) optical disc, a blu-ray disc (BDD) optical disc, a holographic optical disk, another optical medium, a secure digital (SD) card, a micro secure digital (microSD) card, a Memory Stick® card, a smartcard chip, a EMV chip, a subscriber identity module (SIM) card, a mini/micro/nano/pico SIM card, another integrated circuit (IC) chip/card, random access memory (RAM), static RAM (SRAM), dynamic RAM (DRAM), read-only memory (ROM), programmable read-only memory (PROM), erasable programmable read-only memory (EPROM), electrically erasable programmable read-only memory (EEPROM), flash EPROM (FLASHEPROM), cache memory (L1/L2/L3/L4/L5/L#), resistive random-access memory (RRAM/ReRAM), phase change memory (PCM), spin transfer torque RAM (STT-RAM), another memory chip or cartridge, and/or a combination thereof.

The storage device 1230 can include software services, servers, services, etc., that when the code that defines such software is executed by the processor 1210, it causes the system to perform a function. In some embodiments, a hardware service that performs a particular function can include the software component stored in a computer-readable medium in connection with the necessary hardware components, such as processor 1210, connection 1205, output device 1235, etc., to carry out the function.

As used herein, the term “computer-readable medium” includes, but is not limited to, portable or non-portable storage devices, optical storage devices, and various other mediums capable of storing, containing, or carrying instruction(s) and/or data. A computer-readable medium may include a non-transitory medium in which data can be stored and that does not include carrier waves and/or transitory electronic signals propagating wirelessly or over wired connections. Examples of a non-transitory medium may include, but are not limited to, a magnetic disk or tape, optical storage media such as compact disk (CD) or digital versatile disk (DVD), flash memory, memory or memory devices. A computer-readable medium may have stored thereon code and/or machine-executable instructions that may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted using any suitable means including memory sharing, message passing, token passing, network transmission, or the like.

In some embodiments the computer-readable storage devices, mediums, and memories can include a cable or wireless signal containing a bit stream and the like. However, when mentioned, non-transitory computer-readable storage media expressly exclude media such as energy, carrier signals, electromagnetic waves, and signals per se.

Specific details are provided in the description above to provide a thorough understanding of the embodiments and examples provided herein. However, it will be understood by one of ordinary skill in the art that the embodiments may be practiced without these specific details. For clarity of explanation, in some instances the present technology may be presented as including individual functional blocks including functional blocks comprising devices, device components, steps or routines in a method embodied in software, or combinations of hardware and software. Additional components may be used other than those shown in the figures and/or described herein. For example, circuits, systems, networks, processes, and other components may be shown as components in block diagram form in order not to obscure the embodiments in unnecessary detail. In other instances, well-known circuits, processes, algorithms, structures, and techniques may be shown without unnecessary detail in order to avoid obscuring the embodiments.

Individual embodiments may be described above as a process or method which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

Processes and methods according to the above-described examples can be implemented using computer-executable instructions that are stored or otherwise available from computer-readable media. Such instructions can include, for example, instructions and data which cause or otherwise configure a general purpose computer, special purpose computer, or a processing device to perform a certain function or group of functions. Portions of computer resources used can be accessible over a network. The computer executable instructions may be, for example, binaries, intermediate format instructions such as assembly language, firmware, source code, etc. Examples of computer-readable media that may be used to store instructions, information used, and/or information created during methods according to described examples include magnetic or optical disks, flash memory, USB devices provided with non-volatile memory, networked storage devices, and so on.

Devices implementing processes and methods according to these disclosures can include hardware, software, firmware, middleware, microcode, hardware description languages, or any combination thereof, and can take any of a variety of form factors. When implemented in software, firmware, middleware, or microcode, the program code or code segments to perform the necessary tasks (e.g., a computer-program product) may be stored in a computer-readable or machine-readable medium. A processor(s) may perform the necessary tasks. Typical examples of form factors include laptops, smart phones, mobile phones, tablet devices or other small form factor personal computers, personal digital assistants, rackmount devices, standalone devices, and so on. Functionality described herein also can be embodied in peripherals or add-in cards. Such functionality can also be implemented on a circuit board among different chips or different processes executing in a single device, by way of further example.

The instructions, media for conveying such instructions, computing resources for executing them, and other structures for supporting such computing resources are example means for providing the functions described in the disclosure.

In the foregoing description, aspects of the application are described with reference to specific embodiments thereof, but those skilled in the art will recognize that the application is not limited thereto. Thus, while illustrative embodiments of the application have been described in detail herein, it is to be understood that the inventive concepts may be otherwise variously embodied and employed, and that the appended claims are intended to be construed to include such variations, except as limited by the prior art. Various features and aspects of the above-described application may be used individually or jointly. Further, embodiments can be utilized in any number of environments and applications beyond those described herein without departing from the broader spirit and scope of the specification. The specification and drawings are, accordingly, to be regarded as illustrative rather than restrictive. For the purposes of illustration, methods were described in a particular order. It should be appreciated that in alternate embodiments, the methods may be performed in a different order than that described.

One of ordinary skill will appreciate that the less than (“<”) and greater than (“>”) symbols or terminology used herein can be replaced with less than or equal to (“≤”) and greater than or equal to (“≥”) symbols, respectively, without departing from the scope of this description.

Where components are described as being “configured to” perform certain operations, such configuration can be accomplished, for example, by designing electronic circuits or other hardware to perform the operation, by programming programmable electronic circuits (e.g., microprocessors, or other suitable electronic circuits) to perform the operation, or any combination thereof.

The phrase “coupled to” refers to any component that is physically connected to another component either directly or indirectly, and/or any component that is in communication with another component (e.g., connected to the other component over a wired or wireless connection, and/or other suitable communication interface) either directly or indirectly.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

The various illustrative logical blocks, modules, circuits, and algorithm steps described in connection with the embodiments disclosed herein may be implemented as electronic hardware, computer software, firmware, or combinations thereof. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present application.

The techniques described herein may also be implemented in electronic hardware, computer software, firmware, or any combination thereof. Such techniques may be implemented in any of a variety of devices such as general purposes computers, wireless communication device handsets, or integrated circuit devices having multiple uses including application in wireless communication device handsets and other devices. Any features described as modules or components may be implemented together in an integrated logic device or separately as discrete but interoperable logic devices. If implemented in software, the techniques may be realized at least in part by a computer-readable data storage medium comprising program code including instructions that, when executed, performs one or more of the methods described above. The computer-readable data storage medium may form part of a computer program product, which may include packaging materials. The computer-readable medium may comprise memory or data storage media, such as random access memory (RAM) such as synchronous dynamic random access memory (SDRAM), read-only memory (ROM), non-volatile random access memory (NVRAM), electrically erasable programmable read-only memory (EEPROM), FLASH memory, magnetic or optical data storage media, and the like. The techniques additionally, or alternatively, may be realized at least in part by a computer-readable communication medium that carries or communicates program code in the form of instructions or data structures and that can be accessed, read, and/or executed by a computer, such as propagated signals or waves.

The program code may be executed by a processor, which may include one or more processors, such as one or more digital signal processors (DSPs), general purpose microprocessors, an application specific integrated circuits (ASICs), field programmable logic arrays (FPGAs), or other equivalent integrated or discrete logic circuitry. Such a processor may be configured to perform any of the techniques described in this disclosure. A general purpose processor may be a microprocessor; but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Accordingly, the term “processor,” as used herein may refer to any of the foregoing structure, any combination of the foregoing structure, or any other structure or apparatus suitable for implementation of the techniques described herein.

Illustrative aspects of the disclosure include:

Aspect 1: An apparatus comprising: a first substrate comprising a first aperture; and a second substrate comprising a first meta-lens; wherein the first substrate and the second substrate are mechanically coupled such that at least a first portion of the first aperture is disposed over at least a second portion of the first meta-lens.

Aspect 2: The apparatus of aspect 1, wherein: the first substrate comprises a second aperture; the second substrate comprises a second meta-lens; and the first substrate and the second substrate are mechanically coupled such that a third portion of the second aperture is disposed over a fourth portion of the second meta-lens.

Aspect 3: The apparatus of aspect 1 or aspect 2, wherein a first meta-lens module comprises the first aperture and the first meta-lens.

Aspect 4: The apparatus of aspect 2 or aspect 3, wherein a second meta-lens module comprises the second aperture and the second meta-lens.

Aspect 5: The apparatus of any one of aspects 1 to 4, wherein: the first substrate comprises a first wafer and a plurality of apertures; the plurality of apertures comprises the first aperture; the second substrate comprises a second wafer and a plurality of meta-lenses; and the plurality of meta-lenses comprises the first meta-lens.

Aspect 6: The apparatus of any one of aspects 1 to 5, further comprising: a third substrate comprising an optical sensor, wherein the first substrate, the second substrate, and the third substrate are mechanically coupled such that: at least the first portion of the first aperture is disposed above at least the second portion of the first meta-lens; at least a third portion of the first meta-lens is spaced apart from at least a fourth portion of the optical sensor; and at least the second portion of the first meta-lens is disposed over at least a fifth portion of the optical sensor.

Aspect 7: The apparatus of aspect 6, wherein: the third substrate comprises a third wafer and a plurality of optical sensors, wherein the plurality of optical sensors comprises the optical sensor.

Aspect 8: The apparatus of any one of aspects 5 to 7, wherein: the plurality of apertures is disposed on the first substrate with a first pitch; the plurality of meta-lenses is disposed on the second substrate with a second pitch; and the first pitch and the second pitch are equal.

Aspect 9: The apparatus of aspect 8, wherein: the plurality of optical sensors is disposed on the third substrate with a third pitch; and the first pitch, the second pitch, and the third pitch are equal.

Aspect 10: The apparatus of aspect any one of aspects 7 to 9, wherein a fourth wafer comprises a spacer structure disposed between the first wafer and the second wafer and wherein the first wafer, the second wafer, and the fourth wafer are mechanically coupled.

Aspect 11: The apparatus of any one of aspects 7 to 10, wherein the first meta-lens and the optical sensor are separated by a focal length of the first meta-lens.

Aspect 12: The apparatus of any one of aspects 1 to 11, further comprising an optical filter disposed between the first substrate and the second substrate.

Aspect 13: The apparatus of any one of aspects 1 to 11, further comprising a spacer structure disposed between first substrate and the second substrate.

Aspect 14: The apparatus of aspect 13, wherein the optical filter is disposed between the first substrate and the spacer structure.

Aspect 15: The apparatus of aspect 14, wherein the optical filter is disposed between the second substrate and the spacer structure.

Aspect 16: The apparatus of any one of aspects 12 to 15, wherein the optical filter comprises a band pass filter.

Aspect 17: The apparatus of any one of aspects 1 to 15, wherein the first substrate comprises a first silicon substrate and the second substrate comprises a second silicon substrate.

Aspect 18: The apparatus of any one of aspects 1 to 15, wherein the first substrate comprises a first glass substrate and the second substrate comprises a second glass substrate.

Aspect 19: The apparatus of any one of aspects 10 to 18, wherein the spacer structure comprises a third silicon substrate.

Aspect 20: The apparatus of any one of aspects 10 to 18, wherein the spacer structure comprises a third glass substrate.

Aspect 21: The apparatus of any one of aspects 10 to 18, wherein the spacer structure comprises a structure disposed on the first substrate.

Aspect 22: The apparatus of aspect 21, wherein the structure disposed on the first substrate comprises a plurality of pillars positioned outside of a periphery of the first meta-lens.

Aspect 23: The apparatus of aspect 21, wherein the structure disposed on the first substrate comprises a continuous structure surrounding a periphery of the first meta-lens.

Aspect 24: The apparatus of aspect 21, wherein the structure disposed on the first substrate comprises a dam structure.

Aspect 25: The apparatus of any one of aspects 20 to 24, wherein the structure disposed on the first substrate comprises a polyimide material.

Aspect 26: The apparatus of any one of aspects 20 to 25, wherein the structure disposed on the first substrate comprises an opening and wherein the first meta-lens is positioned within the opening.

Aspect 27: The apparatus of any one of aspects 1 to 26, wherein a fifth substrate is mechanically coupled to the first substrate and the second substrate, wherein the fifth substrate comprises a reconfigurable instruction cell array (RICA).

Aspect 28: The apparatus of aspect 27, wherein the RICA is configured to receive image data from an optical sensor.

Aspect 29: The apparatus of aspect 28, wherein the RICA is further configured to perform one or more image processing operations on the image data.

Aspect 30: The apparatus of aspect 29, wherein the one or more image processing operations comprise generating a depth map, generating a composite image, or stitching together at least a portion of a first image and at least a portion of a second image.

Aspect 31: The apparatus of any one of aspects 1 to 30, further comprising a sixth substrate, different from the second substrate, comprising a third meta-lens disposed thereon, wherein at least an eighth portion of the first meta-lens is disposed above at least a ninth portion of the third meta-lens.

Aspect 32: A method of assembling an optical system comprising: mechanically coupling a first substrate comprising a first aperture and a second substrate comprising a first meta-lens, wherein upon mechanically coupling the first substrate and the second substrate at least a first portion of the first aperture is disposed over at least a second portion of the first meta-lens.

Aspect 33: The method of aspect 32, wherein: the first substrate comprises a second aperture; the second substrate comprises a second meta-lens; and the first substrate and the second substrate are mechanically coupled such that a fifth portion of the second aperture is disposed over a sixth portion of the second meta-lens.

Aspect 34: The method of aspect 32 or aspect 33, wherein a first meta-lens module comprises the first aperture and the first meta-lens.

Aspect 35: The method of aspect 33 or aspect 34, wherein a second meta-lens module comprises the second aperture and the second meta-lens.

Aspect 36: The method of any one of aspects 32 to 35, wherein: the first substrate comprises a first wafer; a plurality of apertures, wherein the plurality of apertures comprises the first aperture; and the second substrate comprises a second wafer and a plurality of meta-lenses, wherein the plurality of meta-lenses comprises the first meta-lens.

Aspect 37: The method of any one of aspects 32 to 36, further comprising: mechanically coupling the first substrate, the second substrate, and a third substrate comprising an optical sensor such that at least the first portion of the first aperture is disposed above at least the second portion of the first meta-lens, and at least the second portion of the first meta-lens is disposed over at least a seventh portion of the optical sensor.

Aspect 38: The method of aspect 37, wherein the third substrate comprises a third wafer and a plurality of optical sensors, wherein the plurality of optical sensors comprises the optical sensor.

Aspect 39: The method of any one of aspects 36 to 38, wherein the first meta-lens and the optical sensor are separated by a focal length of the first meta-lens.

Aspect 40: The method of any one of aspects 32 to 39, further comprising disposing an optical filter between the first substrate and the second substrate.

Aspect 41: The method of any one of aspects 32 to 40, further comprising disposing a spacer structure between the first substrate and the second substrate.

Aspect 42: The method of aspect 41, further comprising mechanically coupling a fourth substrate comprising the spacer structure between the first substrate and the second substrate.

Aspect 43: The method of any one of aspects 40 to 42, further comprising disposing the optical filter between the second substrate and the spacer structure.

Aspect 44: The method of any one of aspects 40 to 42, further comprising disposing the optical filter between the first substrate and the spacer structure.

Aspect 45: The method of any one of aspects 40 to 42, wherein the optical filter comprises a band pass filter.

Aspect 46: The method of any one of aspects 32 to 45, wherein the first substrate comprises a first silicon substrate and the second substrate comprises a second silicon substrate.

Aspect 47: The method of any one of aspects 32 to 45, wherein the first substrate comprises a first glass substrate and the second substrate comprises a second glass substrate.

Aspect 48: A method of optical detection, comprising: receiving light at an aperture, wherein a first substrate comprises the aperture and the aperture allows at least a first portion of the light to pass through the first substrate and prevents at least a second portion of the light from passing through the first substrate; receiving at least the first portion of the light at a meta-lens, wherein a second substrate comprises the meta-lens and the meta-lens focuses at least the first portion of the light at a focal plane; and detecting, by an optical sensor, at least the first portion of the light focused by the meta-lens, wherein a third substrate comprises the optical sensor.

Aspect 49: The method of aspect 48, wherein the first substrate, the second substrate, and the third substrate are mechanically coupled.

Aspect 50: The method of either aspect 48 or aspect 49, wherein the meta-lens and the optical sensor are separated by a separation equal to a focal length of the meta-lens.

Aspect 51: The method of aspect 50, wherein a spacer structure provides at least a portion of the separation.

Aspect 52: The method of any one of aspects 48 to 51, further comprising: generating at least a portion of an image based on detecting the first portion of the light.

Aspect 53: The method of aspect 52, further comprising: receiving at least the portion of the image at a RICA.

Aspect 54: The method of aspect 53, wherein a fourth substrate comprises the RICA and the first substrate, the second substrate, the third substrate, and the fourth substrate are mechanically coupled.

Aspect 55: The method of either aspect 53 or aspect 54, wherein the RICA is configured to perform one or more image processing operations on at least the portion of the image.

Aspect 56: The method of any one of aspects 53 to 55, further comprising generating a depth map based on at least the portion of the image, generating a composite image based on at least the portion of the image, or stitching together at least the portion of the image and at least a portion of another image.

Aspect 57: A non-transitory computer-readable storage medium having stored thereon instructions which, when executed by one or more processors, cause the one or more processors to perform any of the operations of aspects 1 to 56.

Aspect 58: An apparatus comprising means for performing any of the operations of aspects 1 to 56.

What is claimed is:

1. An apparatus comprising:
a first substrate comprising a first aperture; and
a second substrate comprising a first meta-lens;
wherein the first substrate and the second substrate are mechanically coupled such that at least a first portion of the first aperture is disposed over at least a second portion of the first meta-lens.

2. The apparatus of claim 1, wherein:
the first substrate comprises a second aperture;
the second substrate comprises a second meta-lens; and
the first substrate and the second substrate are mechanically coupled such that a third portion of the second aperture is disposed over a fourth portion of the second meta-lens.

3. The apparatus of claim 2, wherein a second meta-lens module comprises the second aperture and the second meta-lens.

4. The apparatus of claim 2, further comprising a sixth substrate, different from the second substrate, comprising a third meta-lens disposed thereon, wherein at least an eighth portion of the first meta-lens is disposed above at least a ninth portion of the third meta-lens.

5. The apparatus of claim 4, wherein the first meta-lens and the third meta-lens comprise a compound lens.

6. The apparatus of claim 1, wherein a first meta-lens module comprises the first aperture and the first meta-lens.

7. The apparatus of claim 1, wherein:
the first substrate comprises a first wafer and a plurality of apertures;
the plurality of apertures comprises the first aperture;
the second substrate comprises a second wafer and a plurality of meta-lenses; and
the plurality of meta-lenses comprises the first meta-lens.

8. The apparatus of claim 7, wherein:
the plurality of apertures is disposed on the first substrate with a first pitch;
the plurality of meta-lenses is disposed on the second substrate with a second pitch; and
the first pitch and the second pitch are equal.

9. The apparatus of claim 8, further comprising:
a third substrate comprising an optical sensor, wherein the first substrate, the second substrate, and the third substrate are mechanically coupled such that:
at least the first portion of the first aperture is disposed above at least the second portion of the first meta-lens;
at least a third portion of the first meta-lens is spaced apart from at least a fourth portion of the optical sensor; and
at least the second portion of the first meta-lens is disposed over at least a fifth portion of the optical sensor.

10. The apparatus of claim 9, wherein:
the third substrate comprises a third wafer and a plurality of optical sensors, wherein the plurality of optical sensors comprises the optical sensor.

11. The apparatus of claim 10, wherein:
the plurality of optical sensors is disposed on the third substrate with a third pitch; and
the first pitch, the second pitch, and the third pitch are equal.

12. The apparatus of claim 10, wherein the first meta-lens and the optical sensor are separated by a focal length of the first meta-lens.

13. The apparatus of claim 10, wherein a fourth substrate comprises a spacer structure disposed between the first substrate and the second substrate and wherein the first substrate, the second substrate, and the fourth substrate are mechanically coupled.

14. The apparatus of claim 1, further comprising an optical filter disposed between the first substrate and the second substrate.

15. The apparatus of claim 14, wherein the optical filter is disposed between the first substrate and a spacer structure disposed between the first substrate and the second substrate.

16. The apparatus of claim 14, wherein the optical filter is disposed between the second substrate and a spacer structure disposed between the first substrate and the second substrate.

17. The apparatus of claim 14, wherein the optical filter comprises a band pass filter.

18. The apparatus of claim 1, wherein the first substrate comprises a first silicon substrate and the second substrate comprises a second silicon substrate.

19. The apparatus of claim 1, wherein the first substrate comprises a first glass substrate and the second substrate comprises a second glass substrate.

20. The apparatus of claim 1, further comprising a spacer structure disposed between the first substrate and the second substrate.

21. The apparatus of claim 20, wherein the spacer structure comprises a third silicon substrate.

22. The apparatus of claim 20, wherein the spacer structure comprises a third glass substrate.

23. The apparatus of claim 20, wherein the spacer structure comprises a structure disposed on the first substrate.

24. The apparatus of claim 23, wherein the structure disposed on the first substrate comprises a plurality of pillars positioned outside of a periphery of the first meta-lens.

25. The apparatus of claim 23, wherein the structure disposed on the first substrate comprises a continuous structure surrounding a periphery of the first meta-lens.

26. The apparatus of claim 23, wherein the structure disposed on the first substrate comprises a dam structure.

27. The apparatus of claim 23, wherein the structure disposed on the first substrate comprises a polyimide material.

28. The apparatus of claim 23, wherein the structure disposed on the first substrate comprises an opening and wherein the first meta-lens is positioned within the opening.

29. The apparatus of claim 1, wherein a fifth substrate is mechanically coupled to the first substrate and the second substrate, the fifth substrate comprising a reconfigurable instruction cell array (RICA).

30. The apparatus of claim 29, wherein the RICA is configured to receive image data from an optical sensor.

31. The apparatus of claim 30, wherein the RICA is further configured to perform one or more image processing operations on the image data.

32. The apparatus of claim 31, wherein the one or more image processing operations comprise generating a depth map, generating a composite image, or stitching together at least a portion of a first image and at least a portion of a second image.

33. A method of optical detection, comprising:
receiving light at an aperture, wherein a first substrate comprises the aperture and the aperture allows at least a first portion of the light to pass through the first substrate and prevents at least a second portion of the light from passing through the first substrate;
receiving at least the first portion of the light at a meta-lens, wherein a second substrate comprises the meta-lens and the meta-lens focuses at least the first portion of the light at a focal plane; and
receiving, by an optical sensor, at least the first portion of the light focused by the meta-lens, wherein a third substrate comprises the optical sensor.

34. The method of claim 33, wherein the first substrate, the second substrate, and the third substrate are mechanically coupled.

35. The method of claim 33, wherein the meta-lens and the optical sensor are separated by a separation equal to a focal length of the meta-lens.

36. The method of claim 35, wherein a spacer structure provides at least a portion of the separation.

37. The method of claim 33, further comprising:
generating at least a portion of an image based on detecting the first portion of the light.

38. The method of claim 37, further comprising:
receiving at least the portion of the image at a RICA.

39. The method of claim 38, wherein a fourth substrate comprises the RICA and the first substrate, the second substrate, the third substrate, and the fourth substrate are mechanically coupled.

40. The method of claim 38, wherein the RICA is configured to perform one or more image processing operations on at least the portion of the image.

41. The method of claim 38, further comprising generating a depth map based on at least the portion of the image, generating a composite image based on at least the portion of the image, or stitching together at least the portion of the image and at least a portion of another image.
